(19) United States
(12) Patent Application Publication
(10) Pub. No.: US 2024/0341089 A1
(43) Pub. Date: Oct. 10, 2024

(54) SEMICONDUCTOR DEVICE AND METHOD FOR MANUFACTURING THE SAME

(71) Applicant: Samsung Electronics Co., Ltd., Suwon-si (KR)

(72) Inventors: Hosang LEE, Suwon-si (KR); Taejin PARK, Suwon-si (KR); Hyunjin LEE, Suwon-si (KR); Heejae CHAE, Suwon-si (KR); Yun CHOI, Suwon-si (KR)

(73) Assignee: Samsung Electronics Co., Ltd., Suwon-si (KR)

(21) Appl. No.: 18/474,699

(22) Filed: Sep. 26, 2023

(30) Foreign Application Priority Data
Apr. 7, 2023 (KR) 10-2023-0046395

(51) Int. Cl. H10B 12/00

(52) U.S. Cl. CPC H10B 12/485; H10B 12/02; H10B 12/482

(57) ABSTRACT

A semiconductor device according to some example embodiments includes: a substrate that includes an active region between element isolation layers; a word line that overlaps the active region and extends in a first direction; a bit line that overlaps the active region and extends in a second direction crossing the first direction; a buried contact connected to the active region; a first pad between and connecting the active region and the bit line; a second pad between and connecting the active region and the buried contact; and a landing pad connected to the buried contact. Each of the element isolation layers includes a first element isolation layer and a second element isolation layer inside the first element isolation layer, and each of the first pad and the second pad are between the element isolation layers.

### CROSS-REFERENCE TO RELATED APPLICATION

This U.S. non-provisional patent application claims priority under 35 U.S.C. § 119 to and the benefit of Korean Patent Application No. 10-2023-0046395 filed in the Korean Intellectual Property Office on Apr. 7, 2023, the entire contents of which are incorporated herein by reference.

### BACKGROUND

The present disclosure relates to semiconductor devices and methods for manufacturing (fabricating) the same.

As a semiconductor device becomes increasingly highly integrated, an individual circuit pattern is becoming finer in order to implement more semiconductor devices in the same area. That is, as a degree of integration of the semiconductor device increases, design rules for components of the semiconductor devices are decreasing.

Structures included in the semiconductor device may be formed through a photo process and an etching process, and a relative position between the structures included in the semiconductor device may be formed differently from that designed due to misalignment occurring during the photo process and/or the etching process.

### SUMMARY

Example embodiments provide semiconductor devices with improved reliability and productivity and methods for manufacturing the semiconductor devices.

A semiconductor device according to some example embodiments includes: a substrate that includes an active region between element isolation layers; a word line that overlaps the active region and extends in a first direction; a bit line that overlaps the active region and extends in a second direction crossing the first direction; a buried contact connected to the active region; a first pad connecting between the active region and the bit line; a second pad connecting the active region and the buried contact; and a landing pad connected to the buried contact. Each of the element isolation layers includes a first element isolation layer and a second element isolation layer inside the first element isolation layer, and each of the first pad and the second pad are between the element isolation layers.

A semiconductor device according to some example embodiments includes: a substrate including active regions; an element isolation layer that includes a first element isolation layer and a second element isolation layer on the first element isolation layer and including a protruding portion protruding in a direction perpendicular to an upper surface of the first element isolation layer and is between the active regions; word lines that overlap the active regions and extend in a first direction; bit lines that overlap the active regions and extend in a second direction crossing the first direction; buried contacts connected to the active regions; first pads connecting between the active regions and the bit lines; second pads connecting between the active regions and the buried contacts; and a pad spacer between the first pads and the protruding portion of the second element isolation layer and between the second pads and the protruding portion of the second element isolation layer. The active regions extend in a third direction oblique to the first direction and the second direction, the active regions spaced apart from each other in parallel along the first direction and the third direction, both end portions of the active regions adjacent along the first direction are aligned so that the both end portions coincide with each other, a lower surface of the pad spacer contacts the first element isolation layer, and a side surface of the pad spacer contacts the second element isolation layer.

A method for manufacturing a semiconductor device according to some example embodiments includes: forming a first trench defining an active region within the substrate; forming a first element isolation layer on an upper surface of the active region and within the first trench; forming a second element isolation layer filling the first trench; etching the first element isolation layer to form a second trench exposing an upper surface of the active region; forming a pad pattern on the active region within the second trench; forming a word line that overlaps the pad pattern and extends in a first direction; and forming a bit line that overlaps the pad pattern and extends in a second direction crossing the first direction. The second element isolation layer is at both sides of the second trench, and in the forming of the word line, the pad pattern is separated into a first pad and a second pad by the word line and the first pad is connected to the bit line.

According to some example embodiments, an electrical characteristic of a semiconductor device may be improved by reducing contact resistance of a channel pattern that contacts a bit line and a landing pad.

A pad portion electrically connecting a bit line structure and an active region and a buried contact and the active region may be formed to be self-aligned between insulating layers included in an element isolation layer (or a device separation layer).

Accordingly, it is possible to prevent or reduce in likelihood the pad portion from being formed at an undesirable position due to misalignment. Thus, a contact area between the bit line structure and the active region and a contact area between the buried contact and the active region may be secured so that the electrical characteristic of the semiconductor device is improved.

### BRIEF DESCRIPTION OF THE DRAWINGS

FIG. 1 is a layout diagram illustrating semiconductor devices according to some example embodiments.

FIG. 2 is a partially enlarged view of a portion P1 of FIG. 1.

FIG. 3 is a cross-sectional view taken along a line A-A′ of FIG. 1.

FIG. 4 is a cross-sectional view taken along a line B-B′ of FIG. 1.

FIG. 5 is a cross-sectional view taken along a line C-C′ of FIG. 1.

FIGS. 6 to 40 are plan views and cross-sectional views for explaining methods for manufacturing semiconductor devices according to example embodiments.

FIGS. 6, 10, 14, 18, 22, 26, 30, 34, 36, 38, and 40 are plan views for explaining methods for manufacturing semiconductor devices according to example embodiments.

FIGS. 7 to 9, 11 to 13, 15 to 17, 19 to 21, 23 to 25, 27 to 29, 31 to 33, 35, 37, and 39 are the cross-sectional views cut along cutting lines of the plan views.

### DETAILED DESCRIPTION

The present disclosure will be described more fully hereinafter with reference to the accompanying drawings, in which example embodiments of the disclosure are shown. As those skilled in the art would realize, the described example embodiments may be modified in various different ways, all without departing from the spirit or scope of the present disclosure.

In order to clearly describe the present disclosure, parts or portions that are irrelevant to the description may be omitted, and identical or similar constituent elements throughout the specification may be denoted by the same reference numerals.

Further, in the drawings, the size and thickness of each element are illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

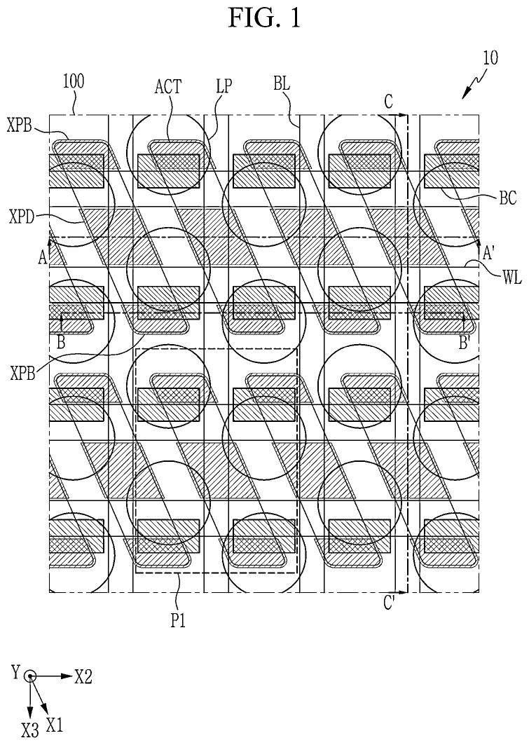

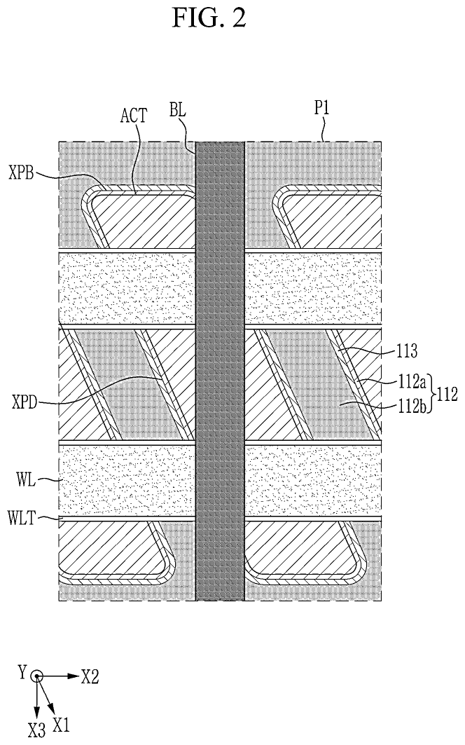

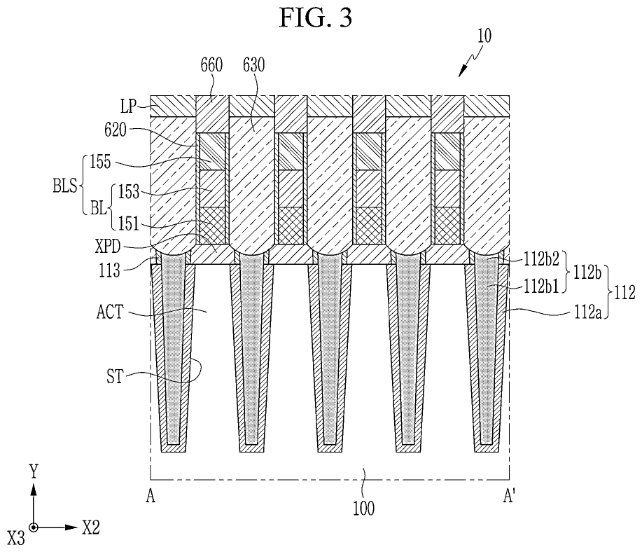

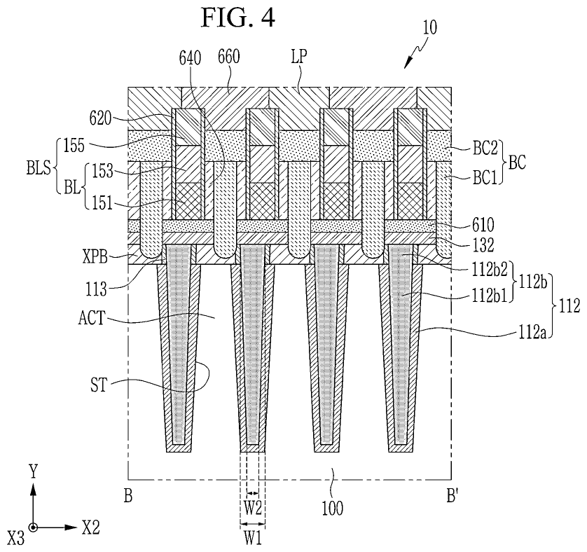

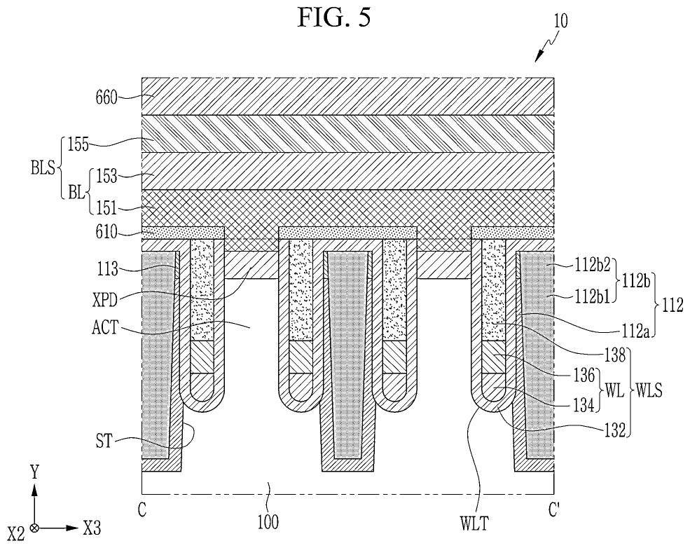

FIG. 1 is a layout diagram illustrating a semiconductor device according to some example embodiments. FIG. 2 is a partially enlarged view of a portion P1 of FIG. 1. FIG. 3 is a cross-sectional view taken along a line A-A′ of FIG. 1. FIG. 4 is a cross-sectional view taken along a line B-B′ of FIG. 1. FIG. 5 is a cross-sectional view taken along a line C-C′ of FIG. 1. In FIG. 2, an illustration of a buried contact BC and a landing pad LP is omitted in order to describe a configuration disposed around an active region ACT.

Referring to FIGS. 1 to 5, the semiconductor device 10 according to some example embodiments may include the active region ACT, and a word line WL and a bit line BL crossing and overlapping the active region ACT.

A substrate 100 may include a semiconductor material. For example, the substrate 100 may include a group IV semiconductor, a group III-V compound semiconductor, a group II-VI compound semiconductor, or the like. For example, the substrate 100 may include a semiconductor such as Si or Ge or a compound semiconductor such as SiGe, SiC, GaAs, InAs, or InP. However, a material of the substrate 100 is not limited thereto, and may be variously changed.

The substrate 100 may have an upper surface parallel to a second direction X2 and a third direction X3, and may have a thickness parallel to a fourth direction Y perpendicular to the second direction X2 and the third direction X3.

The active region ACT may be defined by an element isolation layer (or a device separation layer) 112 disposed within the substrate 100. A plurality of active regions ACT may be disposed within the substrate 100, and the plurality of active regions ACT may be separated from each other by the element isolation layer 112. The element isolation layer 112 may be disposed between the plurality of active regions ACT.

Each of the active regions ACT may have an isolated shape. That is, on a plane, the active regions ACT may respectively correspond to portions of the substrate 100 surrounded by element isolation layers 112.

Each of the active regions ACT may have a bar shape extending along a first direction X1 oblique with respect to the second and third directions X2 and X3. The plurality of active regions ACT may be separated from each other by the element isolation layer 112 such that the separated active regions ACT are disposed to be spaced apart from each other in parallel along the first direction X1. In addition, the active regions ACT may be separated from each other by the element isolation layer 112 such that the separated active regions ACT are disposed to be spaced apart from each other in parallel along the second direction X2.

Accordingly, the active regions ACT may be aligned parallel to each other along the second direction X2. That is, end portions corresponding to each other of the active regions ACT spaced apart from each other along the second direction X2 may be aligned at substantially the same boundary. In other words, one side end portions of the active regions ACT disposed to be spaced apart from each other in parallel along the second direction X2 and the other side end portions facing the one side end portions in the first direction X1 may be disposed at substantially the same boundary in the second direction X2. However, shapes and dispositions of the active regions ACT are not limited thereto, and may be variously changed.

For example, in the plurality of active regions ACT, a one side end portion of one active region ACT may be spaced apart from the other side end portion of the other active region ACT in the first direction X1, and a central portion of the one active region ACT may be aligned with an end portion of the other active region ACT at substantially the same boundary along the second direction X2.

The substrate 100 may include a cell array region and a peripheral circuit region. The cell array region may be a region where a plurality of memory cells are formed, and the plurality of active regions AR may be disposed at the cell array region. The peripheral circuit region may be disposed to surround the cell array region, and elements driving the memory cells may be disposed. Hereinafter, for convenience of description, the cell array region is illustrated, and illustration of the peripheral circuit region is omitted.

The element isolation layer 112 may have a shallow trench isolation (STI) structure having an excellent element isolation characteristic. The element isolation layer 112 may have an aspect ratio in which a cross-sectional width of the element isolation layer 112 in the second direction X2 decreases from an upper surface to a lower surface of the element isolation layer 112. Accordingly, both side surfaces of the element isolation layer 112 may include an inclined surface. However, a cross-sectional shape of the element isolation layer 112 is not limited thereto, and may be variously changed.

The element isolation layer 112 may be made of a silicon oxide, a silicon nitride, or a combination thereof, and/or may include two or more types of insulating materials.

Specifically, an element isolation trench (or an element separation trench) ST may be formed at the substrate 100, and the element isolation layer 112 may be formed of multiple layers including a first element isolation layer 112a and a second element isolation layer 112b sequentially disposed within the element isolation trench ST. However, a configuration of the element isolation layer 112 is not limited thereto, and the element isolation layer 112 may be formed of a single layer.

The first element isolation layer 112a and the second element isolation layer 112b may be sequentially disposed within the element isolation trench ST, and may surround the active regions ACT. Accordingly, the first element isolation layer 112a and the second element isolation layer 112b may be disposed between the active regions ACT, and may define the active regions ACT.

The first element isolation layer 112a may be conformally disposed on an inner side surface of the element isolation trench ST. The second element isolation layer 112b may fill a remaining region of the element isolation trench ST remaining after the first element isolation layer 112a is formed, and may be disposed on the first element isolation layer 112a.

An upper surface of the first element isolation layer 112a may be disposed at substantially the same level as an upper surface of the active region ACT.

The second element isolation layer 112b may include a first portion 112b1 having a side surface and a lower surface surrounded by the first element isolation layer 112a, and a second portion 112b2 that protrudes further in the fourth direction Y perpendicular to the substrate 100 than the upper surface of the first element isolation layer 112a. That is, the second portion 112b2 of the second element isolation layer 112b may extend from the first portion 112b1 toward the fourth direction Y that is a direction perpendicular to the substrate 100, and may be disposed at a higher level than an upper surface of the first element isolation layer 112a. In addition, the second portion 112b2 of the second element isolation layer 112b may be disposed at a higher level than the upper surface of the active region ACT.

A width of the first element isolation layer 112a may be smaller than that of the second element isolation layer 112b. Widths of the first element isolation layer 112a disposed at an inner sidewall and a bottom surface of the element isolation trench ST may be substantially the same. Here, the width of the first element isolation layer 112a may refer to a width between one surface of the first element isolation layer 112a contacting the inner sidewall of the element isolation trench ST and the other surface of the first element isolation layer 112a contacting the second element isolation layer 112b.

Since the element isolation layer 112 has a shape having an aspect ratio in which a width of the element isolation layer 112 in the second direction X2 decreases from an upper surface to a lower surface of the element isolation layer 112, the second element isolation layer 112b may have a first width W1 at an upper surface thereof, the first width W1 may be a maximum width of the second element isolation layer 112b, and may have a second width W2 at a lower surface thereof, the second width W2 may be a minimum width of the second element isolation layer 112b. Here, the first width W1 may mean a width in the second direction X2 of an upper surface of the second element isolation layer 112b disposed between the active regions ACT adjacent in the second direction X2 on a plane. The first width in the X2 direction may be greater than the second width in the X2 direction.

For example, the first width W1 of the second element isolation layer 112b may be about 3.8 nm or more. Since the first width W1 of the second element isolation layer 112b disposed between the active regions ACT has a value of about 3.8 nm or more, the second element isolation layer 112b may not include a void or a seam, and may fill a space within the element isolation trench ST remaining after the first element isolation layer 112a is formed.

In addition, since the first width W1 of the second element isolation layer 112b has the above numerical range, a first pad XPD and a second pad XPB to be described later may be effectively separated and insulated by the second element isolation layer 112b.

However, the numerical range of the second element isolation layer 112b and the width of the first element isolation layer 112a and the width of the second element isolation layer 112b are not limited thereto, and may be variously changed.

The first element isolation layer 112a and the second element isolation layer 112b may include different materials. For example, the first element isolation layer 112a may include a silicon oxide, a silicon oxycarbide, or a combination thereof, and the second element isolation layer 112b may include a silicon nitride, a silicon carbon nitride, or a combination thereof. However, materials included in the first element isolation layer 112a and the second element isolation layer 112b are not limited thereto, and may be variously changed.

The word line WL may extend along the second direction X2, and may cross the active region ACT. The word line WL may overlap the active region ACT, and may serve as a gate electrode. One word line WL may overlap the plurality of active regions ACT adjacent along the second direction X2.

The semiconductor device 10 according to some example embodiments may include a plurality of word lines WL. The plurality of word lines WL may extend parallel to each other along the second direction X2, and may be spaced apart from each other at regular intervals along the third direction X3.

Each of the plurality of active regions ACT may overlap to cross two word lines WL. Each active region ACT may be divided into three portions by the two word lines WL. That is, the central portion of the active region ACT disposed between the two word lines WL may be a portion connected to the bit line BL that will be described later, and both end portions of the active region ACT disposed outside the two word lines WL may be a portion connected to a capacitor (not shown).

A word line trench WLT may be formed in the substrate 100, and a word line structure WLS may be disposed within the word line trench WLT. That is, the word line structure WLS may have a form buried within the substrate 100. A portion of the word line trench WLT may be disposed on the active region ACT, and another portion of the word line trench WLT may be disposed on the element isolation layer 112.

The word line structure WLS may include a gate insulating layer 132, the word line WL including a first word line pattern 134 and a second word line pattern 136 sequentially disposed on the gate insulating layer 132, and a word line capping layer 138 disposed on the word line WL. However, a position, a shape, a structure, or the like of the word line structure WLS are not limited thereto, and may be variously changed. For example, in some example embodiments, the word line WL may be formed of a single layer or may include three or more layers.

The gate insulating layer 132 may be disposed on an upper surface of the element isolation layer 112 and within the word line trench WLT. That is, the gate insulating layer 132 may be conformally formed on upper surfaces of the first element isolation layer 112a, the second element isolation layer 112b, and a pad spacer 113 and the inner side surface of the word line trench WLT.

As shown in FIG. 4, the gate insulating layer 132 may cover second pads XPB, the second element isolation layer 112b, and the pad spacer 113 to be described later.

The gate insulating layer 132 may include a silicon oxide, a silicon nitride, a silicon oxynitride, a high-k material (a high dielectric constant material) having a higher dielectric constant than the silicon oxide, or a combination thereof. However, a position, a shape, a material, or the like of the gate insulating layer 132 is not limited thereto, and may be variously changed.

The word line WL may be disposed on the gate insulating layer 132. Side and bottom surfaces of the word line WL may be surrounded by the gate insulating layer 132. The gate insulating layer 132 may be disposed between the word line WL and the active region ACT. Therefore, the word line WL may not contact or directly contact the active region ACT.

The first word line pattern 134 may include a first conductive material, and the second word line pattern 136 may include a second conductive material having a higher work function than the first conductive material. For example, the first conductive material may include Ti, TiN, TiSiN, Mo, W, WN, WSiN, Cu, Al, Ta, TaN, Ru, Ir, or a combination thereof. The second conductive material may be a polysilicon or silicon germanium doped with an impurity. However, the first conductive material and the second conductive material are not limited thereto, and may be variously changed.

The word line capping layer 138 may be disposed on the word line WL. The word line capping layer 138 may cover or entirely cover an upper surface of the word line WL. A lower surface of the word line capping layer 138 may contact the word line WL. A side surface of the word line capping layer 138 may be covered by the gate insulating layer 132.

The word line capping layer 138 may include a silicon oxide, a silicon nitride, a silicon oxynitride, or a combination thereof. However, a position, a shape, a material, or the like of the word line capping layer 138 is not limited thereto, and may be variously changed.

The semiconductor device 10 according to some example embodiments may further include the first pad XPD and the second pad XPB. The first pad XPD and the second pad XPB may overlap the active region ACT, and may be spaced apart from each other in the first direction X1. A central axis of each of the first and second pads XPD and XPB may be aligned with a central axis of the active region ACT.

The first pad XPD and the second pad XPB may cross the active region ACT, and may be disposed to be separated from each other by the word line trench WLT extending in the second direction X2. The first pad XPD may be disposed at the central portion of the active region ACT disposed between word line trenches WLT, and the second pad XPB may be disposed at both end portions of the active region ACT disposed outside the word line trench WLT. That is, the first pad XPD may overlap the active region ACT disposed between the two word lines WL, and the second pad XPB may overlap the active region ACT disposed outside the word line WL.

That is, on a plane, the active region ACT may be covered or entirely covered by the first pad XPD and the second pad XPB except for a portion where the active region ACT overlaps the word line WL and the word line trench WLT.

A portion of each of the first and second pads XPD and XPB overlapping the active region ACT may protrude outside the active region ACT to cover a portion of the element isolation layer 112. That is, each of edges of the first pad XPD and the second pad XPB overlapping the active region ACT may be disposed further outside an edge of the active region ACT. In other words, widths of the first pad XPD and the second pad XPB, the widths corresponding to a distance between the edges of the first pad XPD and the second pad XPB overlapping the element isolation layer 112 respectively, may be greater than a width of the active region ACT. In addition, the edges of the first pad XPD and the second pad XPB may be disposed parallel to the edge of the active region ACT.

However, the present disclosure is not limited thereto, and in some example embodiments, the active region ACT may be covered by the first pad XPD and the second pad XPB, and the edge of the active region ACT may coincide with the edges of the first pad XPD and the second pad XPB.

Each of the first pad XPD and the second pad XPB may be disposed between the element isolation layers 112. Specifically, each of the first and second pads XPD and XPB may be disposed between second element isolation layers 112b. A portion of each of the first and second pads XPD and XPB may be disposed at the upper surface of the first element isolation layer 112a, and the remaining portion of each of the first and second pads XPD and XPB may be disposed at the upper surface of the active region ACT. That is, each of the first pad XPD and the second pad XPB may overlap the first element isolation layer 112a and the active region ACT in the fourth direction Y that is a direction perpendicular to the substrate 100 or in other words the first element isolation layer 112a may overlap the first pad XPD and the second pad XPB in the fourth direction Y that is a direction perpendicular to the substrate 100. For example, side surfaces of each of the first pad XPD and the second pad XPB may be disposed on the first element isolation layer 112a. Also, the second element isolation layer 112b may not overlap the first pad XPD and the second pad XPB in the fourth direction Y that is a direction perpendicular to the substrate 100.

A lower surface of each of the first pad XPD and the second pad XPB may be disposed at substantially the same level as the upper surface of the first element isolation layer 112a and the upper surface of the active region ACT, and may contact the first element isolation layer 112a and the active region ACT.

As shown in FIGS. 3 and 5, an upper surface of the first pad XPD may be disposed at a higher level than the upper surface of the second element isolation layer 112b, and may contact the bit line BL. As shown in FIG. 3, at least a portion of the upper surface of the first pad XPD may include a curved surface. That is, an upper surface of the first pad XPD contacting a second insulating pattern 630 may include a curved surface.

As shown in FIG. 4, a portion of an upper surface of the second pad XPB may be disposed at substantially the same level as the upper surface of the second element isolation layer 112b, and the remaining portion of the upper surface of the second pad XPB may be disposed at a level lower than the upper surface of the second element isolation layer 112b, and may contact the buried contact BC. However, dispositions and shapes of the first pad XPD and the second pad XPB are not limited thereto, and may be variously changed.

As shown in FIG. 5, the first pad XPD may be disposed between word line capping layers 138, and may overlap the word line capping layer 138 in the third direction X3. That is, the first pad XPD may be disposed parallel to the word line capping layer 138 in the third direction X3. That is, the first pad XPD may be disposed at a level between upper and lower surfaces of the word line capping layer 138. In addition, the upper surface of the first pad XPD may be disposed at a level lower than an upper surface of the word line capping layer 138. However, a relationship between the first pad XPD and the word line capping layer 138 is not limited thereto, and may be variously changed.

Each of the first pad XPD and the second pad XPB may include a polysilicon doped with an impurity or a metal such as W, Mo, Au, Cu, Al, Ni, Co, or the like. However, materials included in the first pad XPD and the second pad XPB are not limited thereto, and may be variously changed.

The pad spacer 113 may be disposed between the first pad XPD and the second portion 112b2 of the second element isolation layer 112b and between the second pad XPB and the second portion 112b2 of the second element isolation layer 112b.

Specifically, the pad spacer 113 may be disposed on the upper surface of the first element isolation layer 112a and a side surface of the second portion 112b2 of the second element isolation layer 112b. For example, the pad spacer may vertically overlap the upper surface of the first element isolation layer 112a in the fourth direction Y perpendicular to the surface of the substrate 100. That is, one side surface of the pad spacer 113 may respectively contact the first and second pads XPD and XPB, and the other side surface of the pad spacer 113 may contact the second portion 112b2 of the second element isolation layer 112b. In addition, a lower surface of the pad spacer 113 may contact the first element isolation layer 112a.

A side surface of the pad spacer 113 may include an inclined surface since it is disposed on the side surface of the second portion 112b2 of the second element isolation layer 112b. In addition, since the pad spacer 113 has a smaller width than that of the first element isolation layer 112a, an inner side surface of the pad spacer 113 may coincide with an inner side surface of the first element isolation layer 112a, and an outer side surface of the pad spacer 113 may be disposed inside than an outer side surface of the first element isolation layer 112a. However, the present disclosure is not limited thereto, and in some example embodiments, the pad spacer 113 may have substantially the same width as that of the first element isolation layer 112a so that the side surface of the pad spacer 113 is aligned at substantially the same boundary as the side surface of the first element isolation layer 112a.

The pad spacer 113 may include a silicon oxide, a silicon nitride, a silicon oxynitride, a silicon oxycarbide, a silicon carbon nitride, a silicon oxycarbonitride, or a combination thereof. For example, the pad spacer 113 may include a silicon oxide. However, a position, a shape, a material, and the like of the pad spacer 113 are not limited thereto, and may be variously changed.

In addition, in some example embodiments, the pad spacer 113 may be omitted. When the pad spacer 113 is omitted, side surfaces of the first and second pads XPD and XPB may contact the side surface of the second portion 112b2 of the second element isolation layer 112b.

As shown in FIG. 4, a first insulating pattern 610 may be disposed on the gate insulating layer 132. The first insulating pattern 610 may include a silicon oxide, a silicon nitride, a silicon oxynitride, or a combination thereof. In addition, although the first insulating pattern 610 is illustrated as being formed of a single layer in FIG. 4, the present disclosure is not limited thereto, and the first insulating pattern 610 may be formed of multiple layers.

The bit line BL may extend along the third direction X3 crossing the second direction X2, and may cross and overlap the active region ACT and the word line WL. The bit line BL may cross in a different direction from the word line WL extending along the second direction X2, and may be disposed above the word line WL. One bit line BL may overlap the plurality of adjacent active regions ACT along the first direction X1.

Each of the plurality of active regions ACT may be connected to the one bit line BL. The bit line BL may be connected to the central portion of the active region ACT through the first pad XPD disposed at the central portion of the active region ACT. However, this is only an example, and a connection form of the bit line BL and the active region ACT may be variously changed.

The semiconductor device 10 according to some example embodiments may include a plurality of bit lines BL. The plurality of bit lines BL may extend in parallel along the third direction X3, and may be spaced apart from each other at regular intervals along the second direction X2.

The bit line BL may be disposed on the first pad XPD and the first insulating pattern 610. The bit line BL may include a first bit line pattern 151 and a second bit line pattern 153 that are sequentially stacked in the fourth direction Y. However, a configuration of the bit line BL is not limited thereto, and may be variously changed. For example, the bit line BL may be formed of a single layer or may include three or more layers.

The first bit line pattern 151 may contact the first pad XPD and the first insulating pattern 610, and the second bit line pattern 153 may contact or directly contact the first bit line pattern 151 and may be connected to the first pad XPD.

The first bit line pattern 151 may include a metal silicide material. For example, the first bit line pattern 151 may include the metal silicide material such as a cobalt silicide, a nickel silicide, a manganese silicide, a titanium silicide, or the like.

The second bit line pattern 153 may include a conductive material. For example, the second bit line pattern 153 may include a polysilicon doped with an impurity or a metal such as W, Mo, Au, Cu, Al, Ni, Co, or the like. In addition, the second bit line pattern 153 may include a metal such as Ti, Ta, or the like and/or a metal nitride such as TIN, TaN, or the like. However, a structure, the number, a material, and the like of the bit line pattern constituting the bit line BL are not limited thereto, and may be variously changed.

A bit line capping layer 155 may be disposed on the bit line BL. The bit line BL and the bit line capping layer 155 may form a bit line structure BLS. The bit line capping layer 155 may overlap the bit line BL and the first pad XPD in the fourth direction Y that is a direction perpendicular to the substrate 100.

A planar shape of the bit line BL may be substantially the same as that of the bit line capping layer 155. The bit line capping layer 155 is illustrated as being in direct contact with the second bit line pattern 153 of the bit line BL, but the present disclosure is not limited thereto. Another layer may be further disposed between the bit line capping layer 155 and the second bit line pattern 153 of the bit line BL.

The bit line capping layer 155 may include an insulating material. For example, the bit line capping layer 155 may have a single-layer or multi-layer structure including a silicon oxide, a silicon nitride, a silicon oxynitride, or a combination thereof. However, a structure and a material of the bit line capping layer 155 are not limited thereto, and may be variously changed.

A bit line spacer 620 may be disposed at both sides of the bit line structure BLS. The bit line spacer 620 may cover side surfaces of the bit line capping layer 155 and the bit line BL. The bit line spacer 620 may extend in the fourth direction Y perpendicular to the substrate 100 along a side surface of the bit line structure BLS. The bit line spacer 620 may contact upper surfaces of the first insulating pattern 610 and the first pad XPD.

In FIG. 3 and FIG. 4, the bit line spacer 620 is illustrated as being formed of a single layer, but the present disclosure is not limited thereto, and the number, structures, and dispositions of layers constituting the bit line spacer 620 may be variously changed.

For example, in some example embodiments, the bit line spacer 620 may be formed of multiple layers made of a combination of various types of insulating materials, or the bit line spacer 620 may be formed of an air spacer structure surrounded by spacers and having an air space.

The bit line spacer 620 may include a silicon nitride, a silicon oxynitride, a silicon oxide, a silicon oxycarbide, a silicon carbon nitride, a silicon oxycarbonitride, or a combination thereof. However, a material of the bit line spacer 620 is not limited thereto, and may be variously changed.

Referring to FIG. 3, the second insulating pattern 630 may be disposed between bit line structures BLS.

The second insulating pattern 630 may be disposed between the bit line structures BLS, and may extend in the fourth direction Y perpendicular to the substrate 100. The second insulating pattern 630 may be formed to fill a space between the bit line structures BLS. The second insulating pattern 630 may cover a side surface of the bit line spacer 620.

The second insulating pattern 630 may contact the second element isolation layer 112b, the pad spacer 113, and the first pad XPD, and may overlap the element isolation layer 112, the pad spacer 113, and the first pad XPD in the fourth direction Y perpendicular to the substrate 100.

A lower surface of the second insulating pattern 630 may include a curved surface. That is, the lower surface of the second insulating pattern 630 may protrude toward the element isolation layer 112, and the lower surface of the second insulating pattern 630 may be disposed at a level between an upper surface and a lower surface of the first pad XPD. That is, since the second insulating pattern 630 is protruded toward the first pad XPD, the upper surface of the first pad XPD may be recessed toward the lower surface of the first pad XPD.

In a process step of forming the second insulating pattern 630, portions of the second element isolation layer 112b, the pad spacer 113, and the first pad XPD may be etched. Accordingly, the upper surface of the second element isolation layer 112b, an upper surface of the pad spacer 113, and a portion of the upper surface of the first pad XPD contacting the lower surface of the second insulating pattern 630 may include a curved surface.

The second insulating pattern 630 may have a single-layer or multi-layer structure including a silicon oxide, a silicon nitride, a silicon oxynitride, or a combination thereof. For example, the second insulating pattern 630 may include a silicon nitride. However, a shape, a disposition, and a material of the second insulating pattern 630 are not limited thereto, and may be variously changed.

Referring to FIG. 4, a third insulating pattern 640 may be disposed between the bit line structures BLS, and may extend in the fourth direction Y perpendicular to the substrate 100. The third insulating pattern 640 may be formed to fill a space between the bit line structure BLS and the buried contact BC that will be described later.

The third insulating pattern 640 may cover a portion of the side surface of the bit line spacer 620. An upper surface of the third insulating pattern 640 may be disposed at a lower level than an upper surface of the bit line spacer 620, and may contact the side surface of the bit line spacer 620.

The third insulating pattern 640 may insulate between the bit line structure BLS and the buried contact BC, and at the same time, the third insulating pattern 640 may serve as a spacer that prevents or reduces in likelihood the bit line structure BLS from being damaged in a process of forming a buried contact hole BCH.

The third insulating pattern 640 may have a single-layer or multi-layer structure including a silicon oxide, a silicon nitride, a silicon oxynitride, or a combination thereof. For example, the third insulating pattern 640 may include a silicon oxide. However, a shape, a disposition, and a material of the third insulating pattern 640 are not limited thereto, and may be variously changed.

As shown in FIG. 4. the buried contact BC may be disposed at a space between the bit line structures BLS. The buried contact BC may include a first buried contact pattern BC1 and a second buried contact pattern BC2.

Specifically, the first buried contact pattern BC1 may extend in the fourth direction Y perpendicular to the substrate 100, and may be disposed between third insulating patterns 640. The first buried contact pattern BC1 may penetrate the first insulating pattern 610 and the gate insulating layer 132, and may contact the second pad XPB.

A lower surface of the first buried contact pattern BC1 may include a curved surface. That is, the lower surface of the first buried contact pattern BC1 may be protruded toward the second pad XPB, and the lower surface of the first buried contact pattern BC1 may be disposed at a level between upper and lower surfaces of the second pad XPB. That is, since the first buried contact pattern BC1 is protruded toward the second pad XPB, the upper surface of the second pad XPB may be recessed toward the lower surface of the second pad XPB.

In a process step of forming the first buried contact pattern BC1, portions of the pad spacer 113 and the second pad XPB may be etched. Accordingly, a portion of the upper surface of the pad spacer 113 and a portion of the upper surface of the second pad XPB contacting the lower surface of the first buried contact pattern BC1 may include a curved surface. In addition, an upper surface of the first buried contact pattern BC1 may be disposed at substantially the same level as the upper surface of the third insulating pattern 640.

The second buried contact pattern BC2 may extend in the second direction X2 crossing the fourth direction Y perpendicular to the substrate 100, and may be disposed on the first buried contact pattern BC1 and the third insulating pattern 640 between the bit line structures BLS. A lower surface of the second buried contact pattern BC2 may contact the upper surface of the first buried contact pattern BC1 and the upper surface of the third insulating pattern 640, and a side surface of the second buried contact pattern BC2 may contact the bit line spacer 620.

Thus, since the first buried contact pattern BC1 and the second buried contact pattern BC2 that has a wider width than that of the first buried contact pattern BC1 are sequentially stacked, the buried contact BC may have an approximate T shape on a cross-section. Accordingly, the buried contact BC may be connected to both end portions of the active region ACT by the second pad XPB disposed at both end portions of the active region ACT on a plane.

The first buried contact pattern BC1 and the second buried contact pattern BC2 may include a conductive material. For example, the first buried contact pattern BC1 and the second buried contact pattern BC2 may include a polysilicon doped with an impurity, a metal silicide, and/or a metal. However, the present disclosure is not limited thereto, and configurations, shapes, dispositions, and materials of the first buried contact pattern BC1 and the second buried contact pattern BC2 may be variously changed.

As shown in FIG. 3 and FIG. 4, the landing pad LP may be disposed on the buried contact BC and the second insulating pattern 630.

The semiconductor device 10 according to some example embodiments may include a plurality of landing pads LP. The plurality of landing pads LP may be disposed to be spaced apart from each other along the second direction X2 and the third direction X3. The landing pads LP may be disposed in a honeycomb shape. That is, the plurality of landing pads LP may be disposed in a zigzag form along the second direction X2, and the plurality of landing pads LP may be disposed in a row along the third direction X3. For example, the plurality of landing pads LP may be alternately disposed in a zigzag form at left and right sides of the bit line BL. However, a disposition form of the plurality of landing pads LP is not limited thereto, and may be variously changed.

The landing pad LP may cover upper surfaces of the buried contact BC and the second insulating pattern 630, and may overlap the buried contact BC and the second insulating pattern 630 in the fourth direction Y perpendicular to the substrate 100.

As shown in FIG. 4, at least portion of the landing pad LP may overlap the bit line spacer 620 and the bit line structure BLS in the fourth direction Y perpendicular to the substrate 100.

An upper surface of the landing pad LP may be disposed at a higher level than an upper surface of the bit line capping layer 155. The bit line spacer 620 may be disposed on both side surfaces of the landing pad LP. In addition, the bit line spacer 620 may be disposed between the landing pad LP and the bit line capping layer 155.

The landing pad LP may contact the buried contact BC, and may be electrically connected to the buried contact BC. The landing pad LP may be electrically connected to the active region ACT through the buried contact BC and the second pad XPB.

The landing pad LP may include a metal, a metal nitride, a polysilicon doped with an impurity, or a combination thereof. For example, the landing pad LP may include tungsten W. However, a configuration and a material of the landing pad LP is not limited thereto, and in some example embodiments, the landing pad LP may be formed of multiple layers. For example, the landing pad LP may further include a metal silicide layer including a metal silicide material such as a cobalt silicide, a nickel silicide, a manganese silicide, or the like and/or a conductive barrier layer including Ti, TiN, or a combination thereof.

A landing pad insulating pattern 660 may be disposed between the plurality of landing pads LP. The landing pad insulating pattern 660 may be formed to fill a space between the plurality of landing pads LP. The plurality of landing pads LP may be separated from each other by the landing pad insulating pattern 660.

As shown in FIG. 3, a lower surface of the landing pad insulating pattern 660 may be disposed at a level lower than an upper surface of the second insulating pattern 630, and may contact an upper surface of the bit line capping layer 155 and the upper surface of the bit line spacer 620.

In addition, as shown in FIG. 4, the landing pad insulating pattern 660 may contact the upper surface of the bit line capping layer 155 and the upper surface of the bit line spacer 620, and a side surface of the landing pad insulating pattern 660 may be disposed on the upper surface of the bit line capping layer 155. The lower surface of the landing pad insulating pattern 660 may be disposed at a level lower than the upper surface of the bit line capping layer 155, and may contact the second buried contact pattern BC2.

The landing pad insulating pattern 660 may be formed of a single layer or multiple layers. For example, the landing pad insulating pattern 660 may include a first material layer and a second material layer that are stacked.

The first material layer may include a silicon oxide or a low-k material (a low dielectric constant material) having a low dielectric constant such as SiOCH or SiOC, and the second material layer may include a silicon nitride or a silicon oxynitride. However, a shape, a disposition, a material, and the like of the landing pad insulating pattern 660 are not limited thereto, and may be variously changed.

According to the semiconductor device 10 according to some example embodiments, since a plurality of first and second pads XPD and XPB separated and insulated by the element isolation layer 112 are formed to be self-aligned between the element isolation layers 112, a photo and etching process of forming a separate insulating pattern for separating the plurality of first and second pads XPD and XPB may be omitted. That is, adjacent first pads XPDs may be separated from each other by the element isolation layer 112 to be self-aligned. In addition, adjacent second pads XPBs may be separated from each other by the element isolation layer 112 to be self-aligned.

In addition, the first pad XPD and the second pad XPB disposed on the active region ACT may be separated from each other by the word line structure WLS formed between the first pad XPD and the second pad XPB, and the first pad XPD and the second pad XPB may be self-aligned on the active region ACT.

Accordingly, a contact area between each of the first pad XPD and the second pad XPB and the active region ACT may be prevented or reduced in likelihood from decreasing, and at the same time, a separate mask and process step for forming and separating the first pad XPD and the second pad XPB may be omitted. The decrease of the contact area may occur since the first pad XPD and the second pad XPB are formed on an undesirable active region ACT due to misalignment that may occur during a photo and etching process.

As described above, the first pad XPD and the second pad XPB may be formed to be self-aligned, so that the contact area between each of the first pad XPD and the second pad XPB and the active region ACT is sufficiently secured and the semiconductor device 10 with improved reliability may be provided by improving an electrical connection characteristic between the bit line BL and the buried contact BC connected to the active region ACT by the first pad XPD and the second pad XPB.

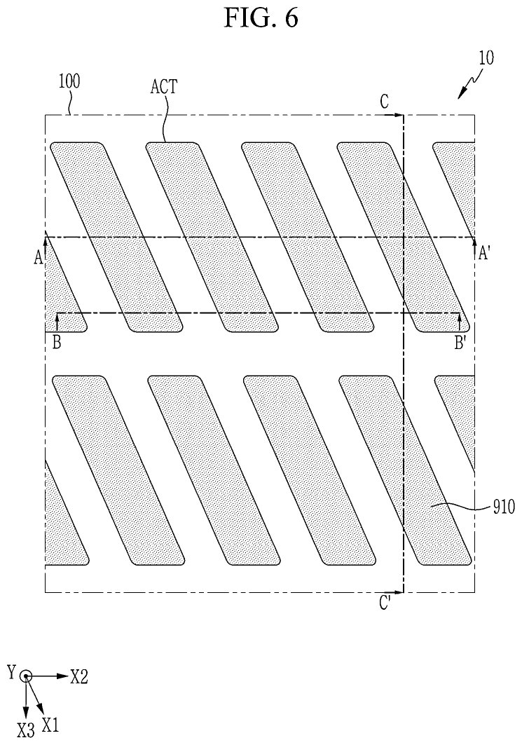

Hereinafter, example embodiments of methods for manufacturing semiconductor devices will be described with reference to FIGS. 6 to 40. Hereinafter, the same configurations described above will be referred to by the same reference numerals, and redundant description will be omitted or simplified, and a difference will be mainly described.

FIGS. 6 to 40 are plan views and cross-sectional views for explaining the method for manufacturing the semiconductor device according to some example embodiments.

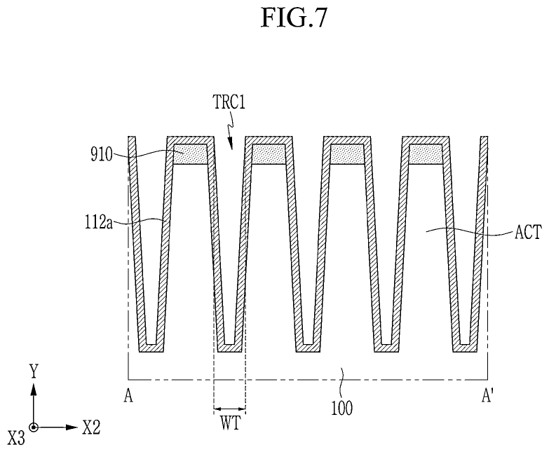

Specifically, FIGS. 6, 10, 14, 18, 22, 26, 30, 34, 36, 38, and 40 are the plan views for explaining the method for manufacturing the semiconductor device according to some example embodiments, and FIGS. 7 to 9, 11 to 13, 15 to 17, 19 to 21, 23 to 25, 27 to 29, 31 to 33, 35, 37, and 39 are the cross-sectional views cut along cutting lines of the plan views.

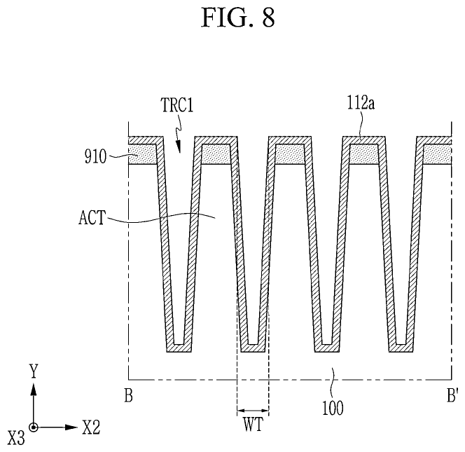

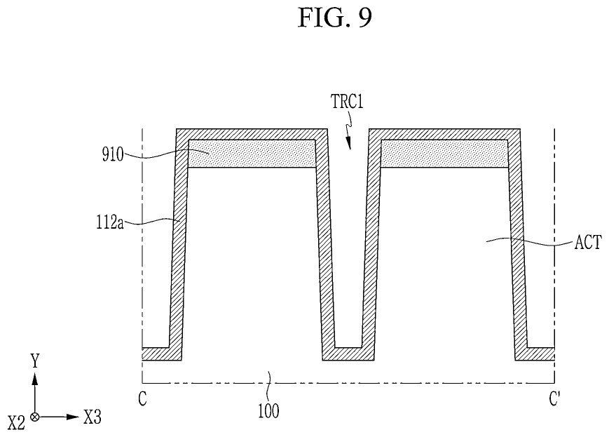

FIG. 7 is a cross-sectional view cut along a line A-A′ of FIG. 6. FIG. 8 is a cross-sectional view cut along a line B-B′ of FIG. 6. FIG. 9 is a cross-sectional view cut along a line C-C′ of FIG. 6.

Referring to FIGS. 6 to 9, after a mask layer is formed on the substrate 100, a mask pattern 910 may be formed by patterning the mask layer.

Subsequently, the mask pattern 910 disposed on the substrate 100 may be used so that a first trench TRC1 for defining the plurality of active regions ACT is formed at the substrate 100 and the first element isolation layer 112a is formed within the first trench TRC1.

The first element isolation layer 112a may be conformally formed on an upper surface of the mask pattern 910 and within the first trench TRC1.

As shown in FIGS. 7 to 9, the first trench TRC1 may have an aspect ratio in which a width of the first trench TRC1 in the second direction X2 decreases toward a bottom surface of the first trench TRC1. Accordingly, an interval between the first element isolation layer 112a formed on an inner side surface disposed at one side of the first trench TRC1 and the first element isolation layer 112a formed on an inner side surface disposed at the other side of the first trench TRC1 may decrease from an upper end portion of the first trench TRC1 toward the bottom surface of the first trench TRC1. That is, the interval between first element isolation layers 112a formed within the first trench TRC1 may be maximum at an uppermost end portion of the first trench TRC1. For example, a trench width WT, which may correspond to a maximum width, between the first element isolation layers 112a within the first trench TRC1 may be about 3.8 nm or more. Here, the trench width WT may mean a maximum width between the first element isolation layers 112a disposed between the active regions ACT adjacent in the second direction X2 on a plane.

Since the trench width WT between the first element isolation layers 112a within the first trench TRC1 has a value of about 3.8 nm or more, in a process step of forming the second element isolation layer 112b that will be described later, the second element isolation layer 112b may not include a void or a seam, and may be formed to fill the first trench TRC1. However, this is illustrative and not limited thereto, and the trench width WT between the first element isolation layers 112a within the first trench TRC1 may be variously changed.

The mask pattern 910 may include a material having etching selectivity with respect to the substrate 100 and the second element isolation layer 112b that will be described later. For example, the mask pattern 910 may include a silicon oxide. However, a method of forming the first trench TRC1 within the substrate 100 and a material included in the mask pattern 910 are not limited thereto, and may be variously changed.

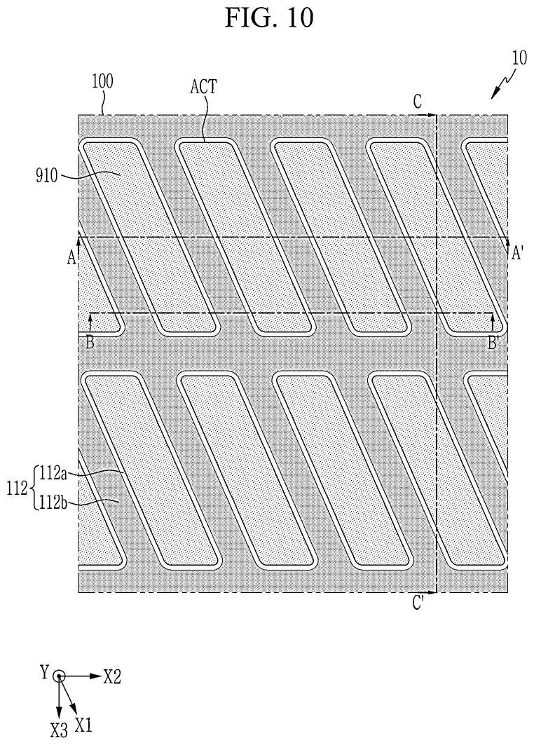

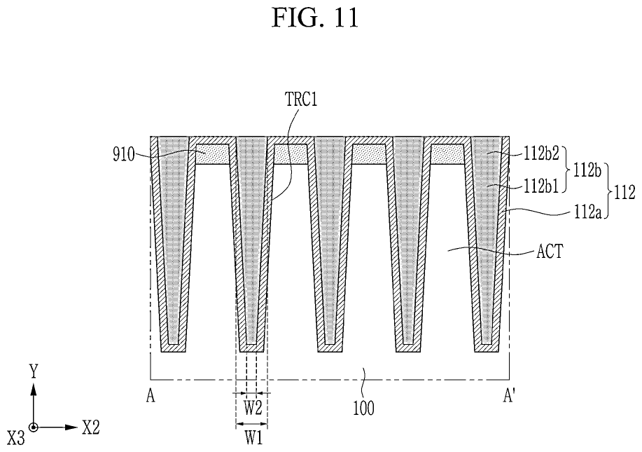

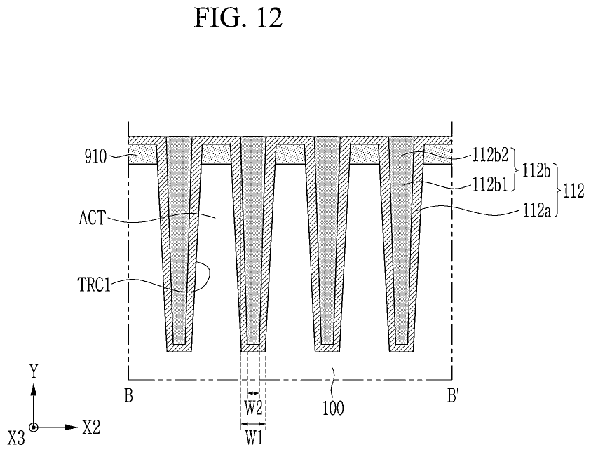

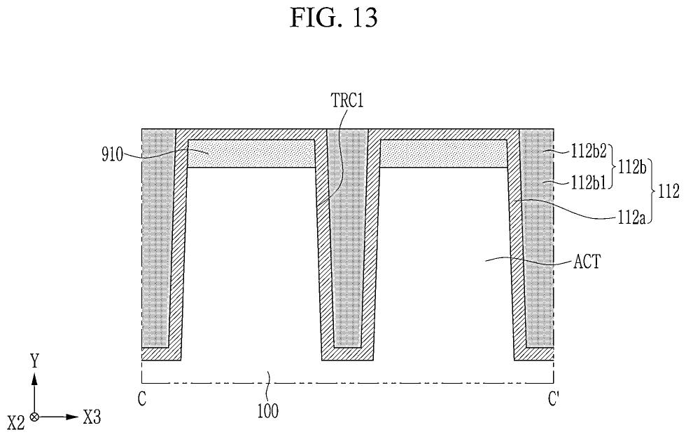

FIG. 11 is a cross-sectional view cut along a line A-A′ of FIG. 10. FIG. 12 is a cross-sectional view cut along a line B-B′ of FIG. 10. FIG. 13 is a cross-sectional view cut along a line C-C′ of FIG. 10.

Subsequently, referring to FIGS. 10 to 13. the second element isolation layer 112b may be formed on the first element isolation layer 112a to fill a region of the first trench TRC1 remaining after the first element isolation layer 112a is formed.

Accordingly, the first element isolation layer 112a and the second element isolation layer 112b may be sequentially formed within the first trench TRC1, and the plurality of active region ACT may be separated from each other by the element isolation layer 112. The first element isolation layer 112a and the second element isolation layer 112b may sequentially surround an outer side of the active region ACT. That is, the element isolation layer 112 is disposed at both sides of each active region ACT. The active region ACT may have the bar shape extending along the first direction X1 oblique with respect to the second direction X2 and the third direction X3 on a plane.

The second element isolation layer 112b may be surrounded by the first element isolation layer 112a. The second element isolation layer 112b may include the first portion 112b1 disposed at a level lower than the upper surface of the active region ACT and the second portion 112b2 disposed at a level higher than the upper surface of the active region ACT. That is, the second portion 112b2 of the second element isolation layer 112b may extend from the first portion 112b1 of the second element isolation layer 112b toward the fourth direction Y, and may be disposed at a level higher than the upper surface of the active region ACT.

In addition, the second portion 112b2 of the second element isolation layer 112b may be disposed at a level higher than the upper surface of the active region ACT. An upper surface of the second portion 112b2 of the second element isolation layer 112b may be disposed at substantially the same level as the upper surface of the first element isolation layer 112a disposed on the active region ACT. That is, in the process step of forming the second element isolation layer 112b, since a portion of the second element isolation layer 112b disposed at a level higher than the upper surface of the first element isolation layer 112a is removed by a planarization process such as an etch back process or a chemical mechanical polishing (CMP) process, the upper surface of the second portion 112b2 of the second element isolation layer 112b may be disposed at substantially the same level as the upper surface of the first element isolation layer 112a.

The element isolation layer 112 formed within the first trench TRC1 may have the aspect ratio in which the cross-sectional width of the element isolation layer 112 in the second direction X2 decreases from the upper surface to the lower surface of the element isolation layer 112. Both side surfaces of the element isolation layer 112 may include an inclined surface.

Accordingly, the second element isolation layer 112b may have the first width W1 at the upper surface thereof, and may have the second width W2 at the lower surface thereof. Here, the first width W1 may mean the width in the second direction X2 of the upper surface of the second element isolation layer 112b disposed between the active regions ACT adjacent in the second direction X2 on a plane.

As described above, since the trench width WT between the first element isolation layers 112a within the first trench TRC1 is about 3.8 nm or more, the first width W1 of the second element isolation layer 112b filling a remaining region of the first trench TRC1 remaining after the first element isolation layer 112a is formed may be about 3.8 nm or more. The cross-sectional shape of the element isolation layer 112 and the width of the second element isolation layer 112b are not limited thereto, and may be variously changed.

The first element isolation layer 112a may include a silicon oxide, a silicon oxycarbide, or a combination thereof, and the second element isolation layer 112b may include a silicon nitride, a silicon carbon nitride, or a combination thereof. However, the present disclosure is not limited thereto, and materials included in the first element isolation layer 112a and the second element isolation layer 112b may be variously changed.

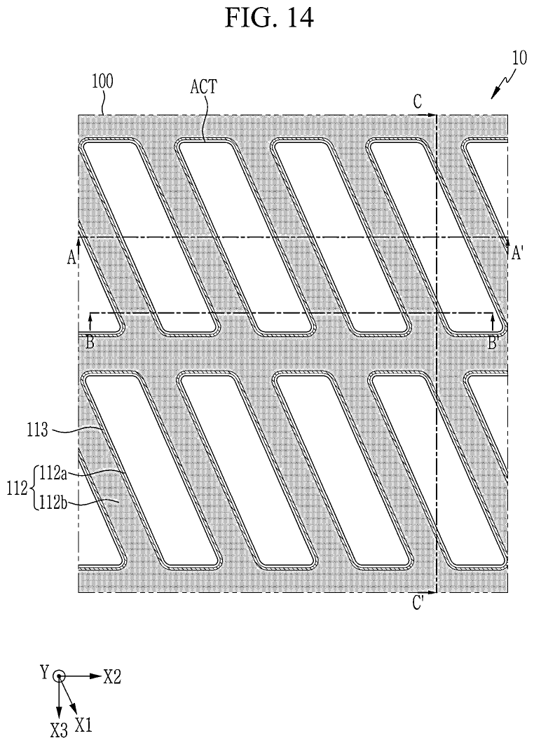

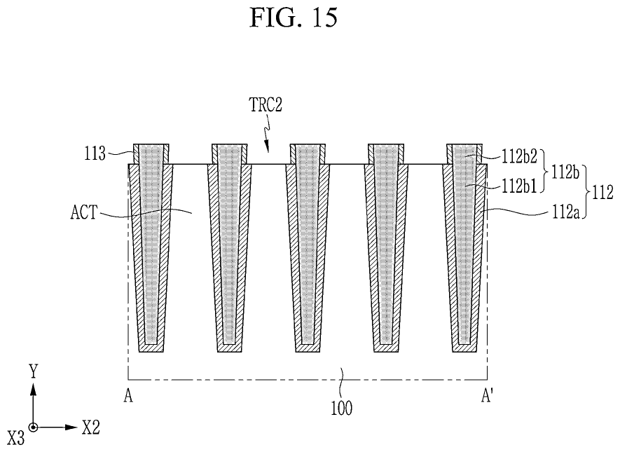

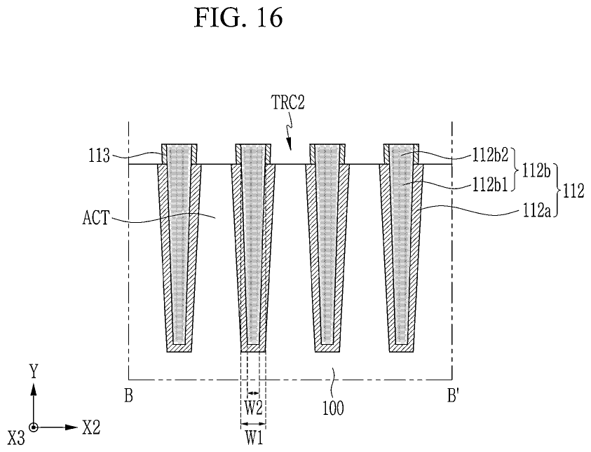

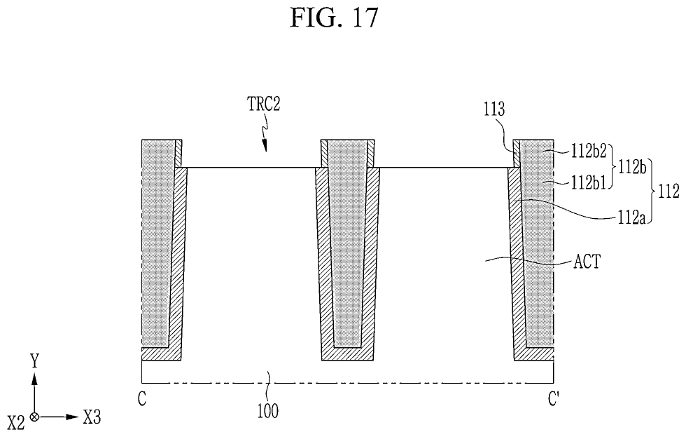

FIG. 15 is a cross-sectional view cut along a line A-A′ of FIG. 14. FIG. 16 is a cross-sectional view cut along a line B-B′ of FIG. 14. FIG. 17 is a cross-sectional view cut along a line C-C′ of FIG. 14.

Subsequently, referring to FIGS. 14 to 17, after a second trench TRC2 is formed by removing the mask pattern 910 and a portion of the first element isolation layer 112a, the pad spacer 113 may be formed at both inner sidewalls of the second trench TRC2.

Specifically, the upper surface of the active region ACT may be exposed by removing the mask pattern 910 disposed on the upper surface of the active region ACT. A portion of the first element isolation layer 112a disposed on the upper surface of the active region ACT may be etched to a level of the upper surface of the active region ACT so that the second portion 112b2 of the second element isolation layer 112b is exposed.

Accordingly, the second trench TRC2 may be defined by the upper surface of the active region ACT, the upper surface of the first element isolation layer 112a, and the side surface of the second portion 112b2 of the second element isolation layer 112b.

When the first element isolation layer 112a and the mask pattern 910 do not have etching selectivity to each other, a process of removing the portion of the first element isolation layer 112a and a process of removing the mask pattern 910 may be simultaneously performed. For example, since the mask pattern 910 and the first element isolation layer 112a have etching selectivity with respect to the substrate 100 and the second element isolation layer 112b, the mask pattern 910 and the first element isolation layer 112a may be etched using an etching material having a high etching selectivity with respect to the mask pattern 910 and the first element isolation layer 112a. However, the present disclosure is not limited thereto, and the process of removing the mask pattern 910 and the first element isolation layer 112a may be variously changed.

For example, in some example embodiments, when the first element isolation layer 112a and the mask pattern 910 have etching selectivity to each other, the process of removing the portion of the first element isolation layer 112a and the process of removing the mask pattern 910 may be sequentially performed.

Subsequently, the pad spacer 113 may be formed on both inner sidewalls of the second trench TRC2.

Specifically, the pad spacer 113 may be formed on the upper surface of the first element isolation layer 112a and the side surface of the second portion 112b2 of the second element isolation layer 112b. That is, the one side surface of the pad spacer 113 may contact the second portion 112b2 of the second element isolation layer 112b, and the lower surface of the pad spacer 113 may contact the first element isolation layer 112a.

In addition, since the side surface of the second portion 112b2 of the second element isolation layer 112b includes an inclined surface, the side surface of the pad spacer 113 formed on the side surface of the second portion 112b2 of the second element isolation layer 112b may include an inclined surface.

A process step of forming the pad spacer 113 may include a process of removing a portion of the pad spacer 113 after the pad spacer 113 is conformally formed on the upper surface of the second element isolation layer 112b and within the second trench TRC2. However, the method of forming the pad spacer 113 is not limited thereto, and may be variously changed.

The pad spacer 113 may include a silicon oxide, a silicon nitride, a silicon oxynitride, a silicon oxycarbide, a silicon carbon nitride, a silicon oxycarbonitride, or a combination thereof. For example, the pad spacer 113 may include a silicon oxide. However, a shape, a material, and the like of the pad spacer 113 are not limited thereto, and may be variously changed. In addition, in some example embodiments, the process step of forming the pad spacer 113 may be omitted.

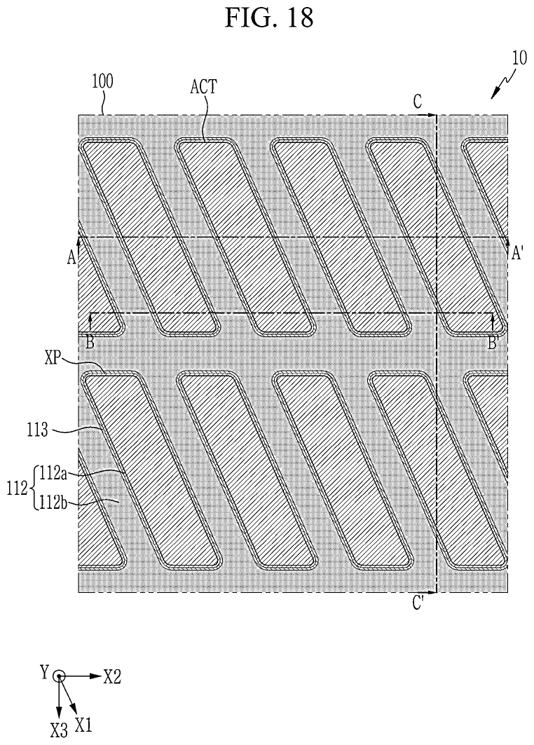

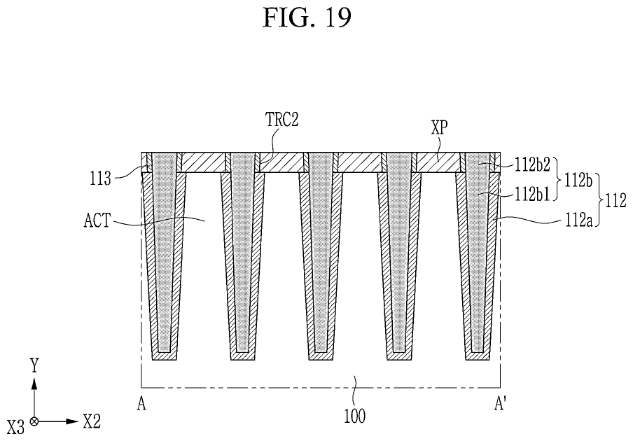

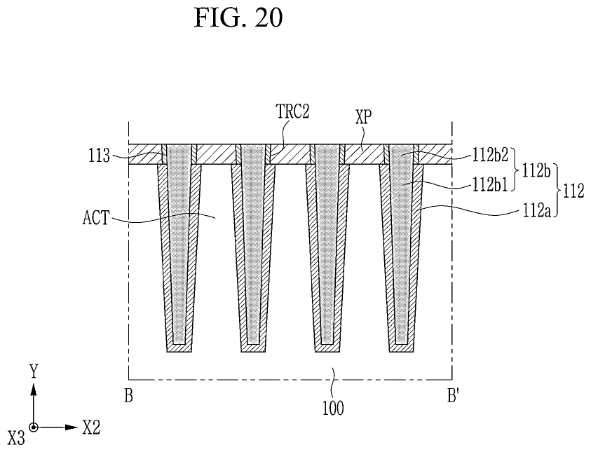

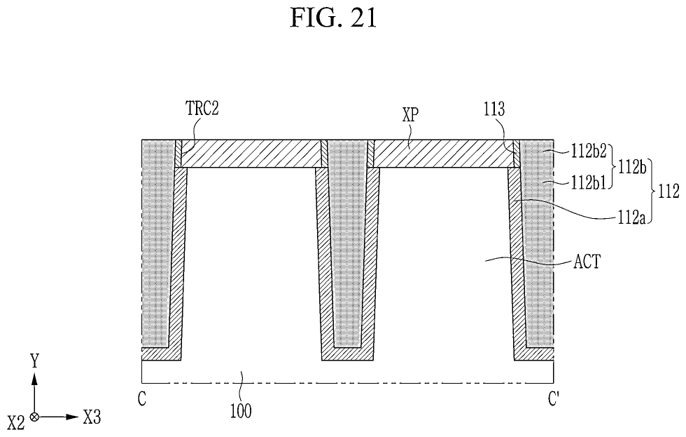

FIG. 19 is a cross-sectional view cut along a line A-A′ of FIG. 18. FIG. 20 is a cross-sectional view cut along a line B-B′ line of FIG. 18. FIG. 21 is a cross-sectional view cut along a line C-C′ of FIG. 18.

Subsequently, referring to FIGS. 18 to 21, a pad pattern XP may be formed within the second trench TRC2.

Specifically, the pad pattern XP may be formed within a region of the second trench TRC2 remaining after the pad spacer 113 is formed. That is, the pad pattern XP may be formed to be self-aligned within the region of the second trench TRC2 remaining after the pad spacer 113 is formed.

As shown in FIG. 18, a planar shape of the pad pattern XP may be similar to that of the active region ACT. A planar area of the pad pattern XP may be larger than a planar area of the active region ACT. Accordingly, an edge of the pad pattern XP disposed on the active region ACT may be disposed outside the edge of the active region ACT. In addition, a central axis of the pad pattern XP formed within the second trench TRC2 may coincide with the central axis of the active region ACT.

As shown in FIGS. 19 to 20, on a cross-section, an upper surface of the pad pattern XP formed within the second trench TRC2 may be disposed at substantially the same level as the upper surface of the second portion 112b2 of the second element isolation layer 112b and the upper surface of the pad spacer 113.

That is, in the process step of forming the pad pattern XP within the second trench TRC2 by self-alignment, since a portion of the pad pattern XP disposed at a level higher than the upper surface of the second portion 112b2 of the second element isolation layer 112b is removed by a planarization process such as an etch back process or a chemical mechanical polishing (CMP) process, the upper surface of the pad pattern XP may be disposed at substantially the same level as the upper surface of the second portion 112b2 of the second element isolation layer 112b.

A lower surface of the pad pattern XP may be disposed at substantially the same level as the upper surface of the first element isolation layer 112a and the upper surface of the active region ACT, and may contact the upper surface of the first element isolation layer 112a and the upper surface of the active region ACT.

The pad pattern XP may include a polysilicon doped with an impurity or a metal such as W, Mo, Au, Cu, Al, Ni, Co, or the like. However, the process for forming the pad pattern XP, a shape, a disposition, and a material of the pad pattern XP are not limited thereto, and may be variously changed.

As described above, since the pad pattern XP is formed to be self-aligned within the second trench TRC2 defined by the element isolation layer 112, a separate photo and etching process for forming and insulating the pad pattern XP may be omitted. Accordingly, the pad pattern XP may be prevented or reduced in likelihood from being formed on an undesirable active region ACT due to misalignment in a photo and etching process, and at the same time, the separate photo and etching process may be omitted.

Therefore, since the pad pattern XP is formed to be self-aligned, a contact area between the pad pattern XP and the active region ACT may be sufficiently secured, and productivity may be improved by omitting the process.

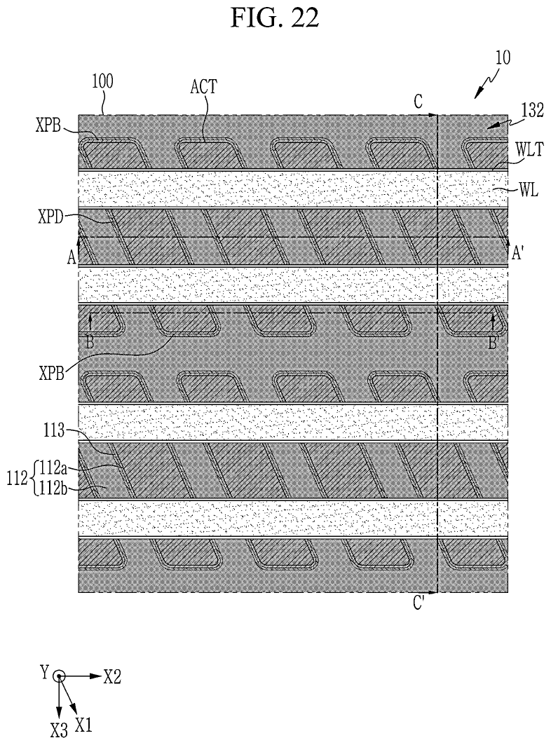

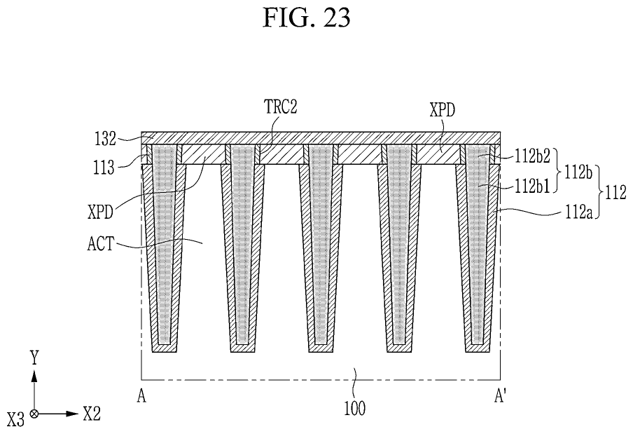

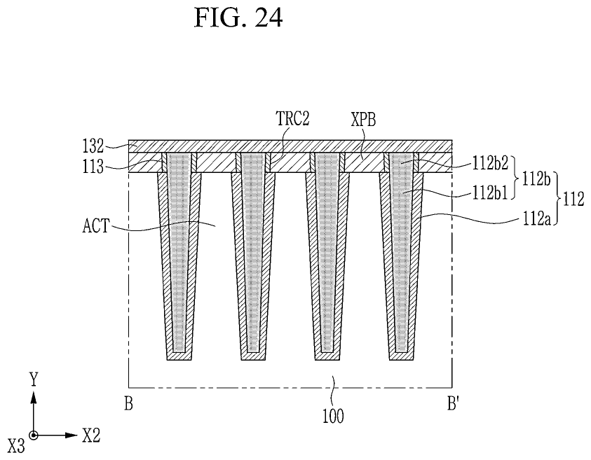

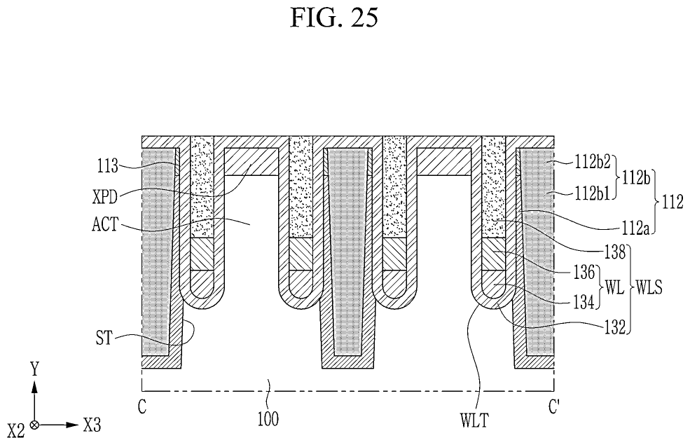

FIG. 23 is a cross-sectional view cut along a line A-A′ of FIG. 22. FIG. 24 is a cross-sectional view cut along a line B-B′ of FIG. 22. FIG. 25 is a cross-sectional view cut along a line C-C′ of FIG. 22.

Subsequently, referring to FIGS. 22 to 25, the word line structure WLS may be formed on the active region ACT and the element isolation layer 112.

Specifically, as shown in FIG. 22, the word line trench WLT extending along the second direction X2 and crossing the active region ACT may be formed. Subsequently, after the gate insulating layer 132 is formed at a front surface of the substrate 100, the word line WL may be formed on the gate insulating layer 132 disposed within the word line trench WLT. Although not shown in FIG. 22, the word line capping layer 138 may be formed on the word line WL.

The word line WL may extend along the second direction X2, and may cross the active region ACT. The word line WL may overlap the active region ACT. One word line WL may overlap the plurality of active regions ACT adjacent along the second direction X2.

The semiconductor device 10 according to some example embodiments may include the plurality of word lines WL. The plurality of word lines WL may extend parallel to each other along the second direction X2, and may be spaced apart from each other at regular intervals along the third direction X3.

Each of the plurality of active regions ACT may overlap to cross two word lines WL. Each active region ACT may be divided into three portions by two word line structures WLS.

Accordingly, each pad pattern XP disposed on the active region ACT may be separated into the first pad XPD and the second pad XPB by the word line trench WLT. That is, a central portion of the pad pattern XP overlapping the active region ACT disposed between the two word line trenches WLT may become the first pad XPD, and both end portions of the pad pattern XP overlapping both end portions of the active region ACT disposed outside the word line trench WLT may become the second pad XPB. That is, the central portion of the pad pattern XP overlapping the active region ACT disposed between the two word lines WL may become the first pad XPD, and both end portions of the pad pattern XP overlapping both end portions of the active region ACT disposed outside the word line WL may become the second pad XPB.

Accordingly, on a plane, the active region ACT may be covered or entirely covered by the first pad XPD and the second pad XPB except for a portion where the active region ACT overlaps the word line WL and the word line trench WLT.

As shown in FIGS. 23 and 24, the gate insulating layer 132 may be disposed on the element isolation layer 112, the pad spacer 113, the first pad XPD, and the second pad XPB. The gate insulating layer 132 may cover the upper surface of the second element isolation layer 112b, the upper surface of the pad spacer 113, the upper surface of the first pad XPD, and the upper surface of the second pad XPB.

As shown in FIG. 25, the word line trench WLT may be formed by patterning the active regions ACT and the element isolation layer 112. In the process step of forming the word line trench WLT, etching conditions for the substrate 100 and the element isolation layer 112 may be changed so that the element isolation layer 112 is etched more deeply than the substrate 100. Accordingly, a difference in depth may occur depending on a degree of etching of the substrate 100 and a degree of etching of the element isolation layer 112, and a bottom surface of the word line trench WLT may be curved.

Subsequently, the gate insulating layer 132 may be conformally formed on the upper surface of the element isolation layer 112, the upper surface of the pad spacer 113, the upper surface of the first pad XPD, and within the word line trench WLT.

The gate insulating layer 132 may be formed using at least one of physical vapor deposition (PVD), thermal chemical vapor deposition (CVD), low pressure chemical vapor deposition (LP-CVD), plasma enhanced chemical vapor deposition (PE-CVD), and atomic layer deposition (ALD) technologies. However, the method of forming the gate insulating layer 132 is not limited thereto, and may be variously changed.

Subsequently, the first word line pattern 134 and the second word line pattern 136 may be sequentially formed within the word line trench WLT. The first word line pattern 134 and the second word line pattern 136 may be sequentially formed on the gate insulating layer 132. The first word line pattern 134 and the second word line pattern 136 may constitute the word line WL.

The first word line pattern 134 may include the first conductive material, and the second word line pattern 136 may include the second conductive material having a higher work function than the first conductive material. For example, the first conductive material may be one of Ti, TiN, TiSiN, Mo, W, WN, WSIN, Cu, Al, Ta, TaN, Ru, and Ir. The second conductive material may be a polysilicon or silicon germanium doped with an impurity. However, the first conductive material and the second conductive material are not limited thereto, and may be variously changed.

Subsequently, the word line capping layer 138 may be formed within the word line trench WLT. The word line capping layer 138 may be formed on the word line WL.

The upper surface of the word line capping layer 138 may be disposed at substantially the same level as an upper surface of the gate insulating layer 132 disposed on the upper surface of the element isolation layer 112, the upper surface of the pad spacer 113, and the upper surface of the first pad XPD. That is, in the process step of forming the word line capping layer 138, since a portion of the word line capping layer 138 disposed at a level higher than the upper surface of the gate insulating layer 132 is removed by a planarization process such as an etch back process or a chemical mechanical polishing (CMP) process, the upper surface of the word line capping layer 138 may be disposed at substantially the same level as the upper surface of the gate insulating layer 132.

The word line capping layer 138 may include a silicon oxide, a silicon nitride, a silicon oxynitride, or a combination thereof. However, a position, a shape, a material, and the like of the word line capping layer 138 are not limited thereto, and may be variously changed.

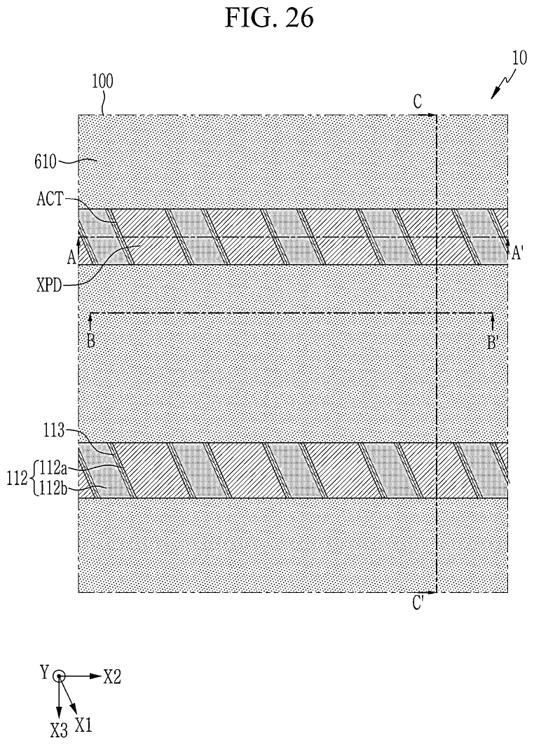

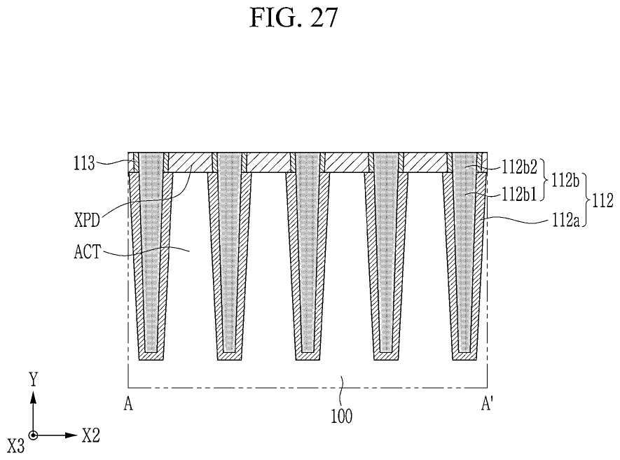

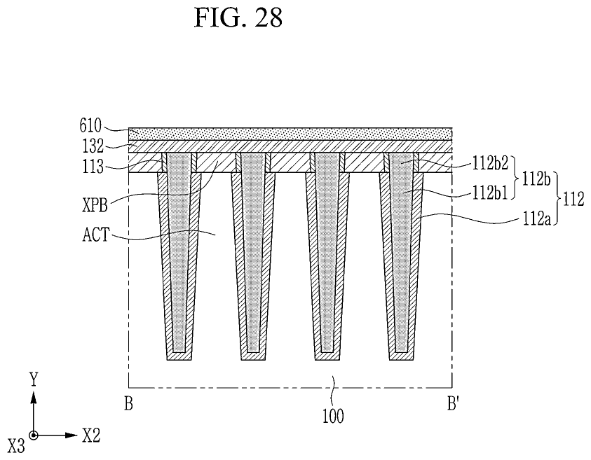

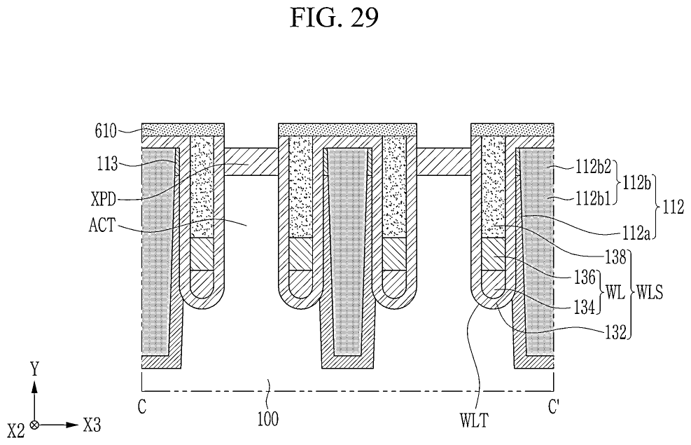

FIG. 27 is a cross-sectional view cut along a line A-A′ of FIG. 26. FIG. 28 is a cross-sectional view cut along a line B-B′ line of FIG. 26. FIG. 29 is a cross-sectional view cut along a line C-C′ of FIG. 26.

Subsequently, referring to FIGS. 26 to 29 together with FIG. 22, the first insulating pattern 610 may be formed on the gate insulating layer 132 and the word lines WL. That is, on a plane, the first insulating pattern 610 may extend along the second direction X2, and first insulating patterns 610 may be disposed to be spaced apart from each other in the third direction X3. The first insulating pattern 610 may overlap the gate insulating layer 132 disposed between two word lines WL and two word lines WL.

The process step of forming the first insulating pattern 610 may include patterning the first insulating pattern 610 and etching the gate insulating layer 132 disposed on the first pad XPD using the patterned first insulating pattern 610 as an etching mask.

That is, the first pad XPD may be exposed by removing a portion of the gate insulating layer 132 using the gate insulating layer 132 and the first insulating pattern 610 having etching selectivity as an etching mask.

As shown in FIG. 29, the first pad XPD may be disposed between the word line capping layers 138, and may overlap the word line capping layer 138 in the third direction X3. That is, the first pad XPD may be disposed parallel to the word line capping layer 138 in the third direction X3. That is, the first pad XPD may be disposed at a level between the upper and lower surfaces of the word line capping layer 138. In addition, the upper surface of the first pad XPD may be disposed at a level lower than the upper surface of the word line capping layer 138, and the lower surface of the first pad XPD may be disposed at a level higher than the lower surface of the word line capping layer 138. However, a relationship between the first pad XPD and the word line capping layer 138 is not limited thereto, and may be variously changed.

Accordingly, the first pads XPD, the pad spacer 113, and the element isolation layer 112 may be exposed between the first insulating patterns 610. That is, the first pad XPD disposed on the central portion of the active region ACT disposed between the first insulating patterns 610 on a plane may be exposed, and the gate insulating layer 132 that is disposed on the second pads XPB disposed on both end portions of the active region ACT overlapping the insulating pattern 610 may be covered by the first insulating pattern 610.

The first insulating pattern 610 may include a silicon oxide, a silicon nitride, a silicon oxynitride, or a combination thereof. For example, the first insulating pattern 610 may include a silicon nitride. However, a material included in the first insulating pattern 610 is not limited thereto, and may be variously changed.

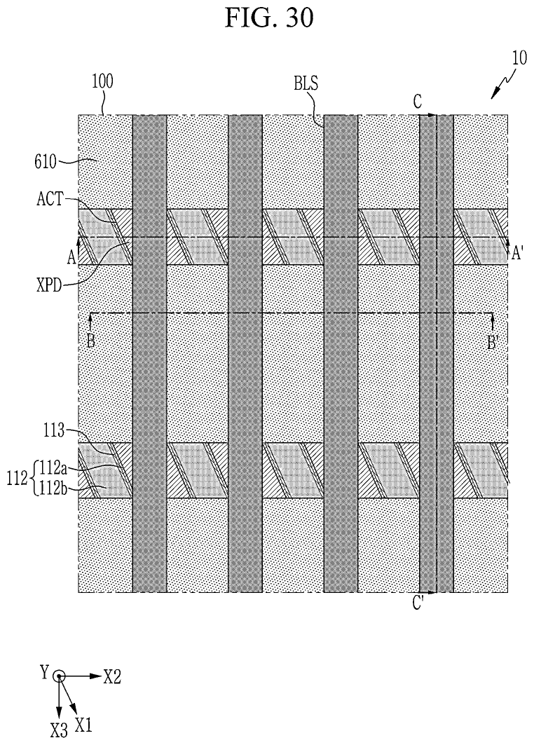

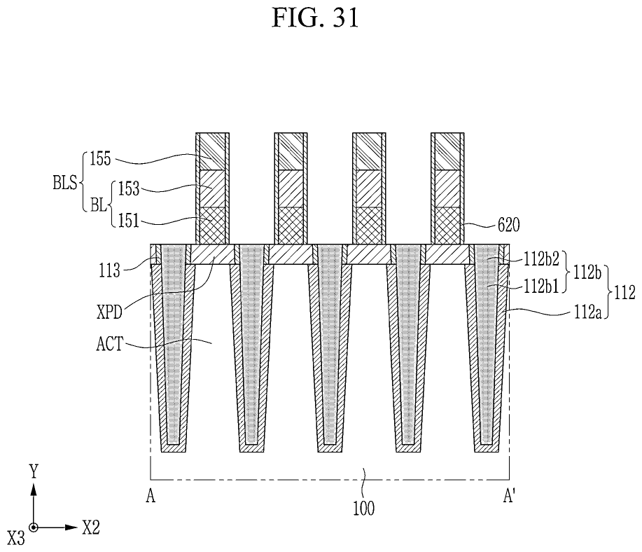

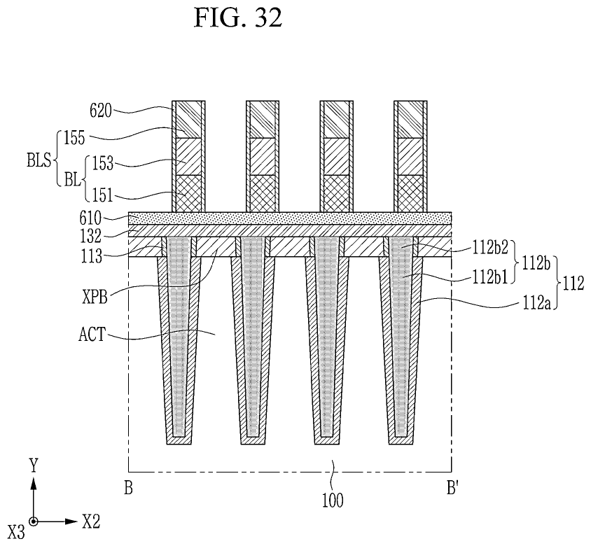

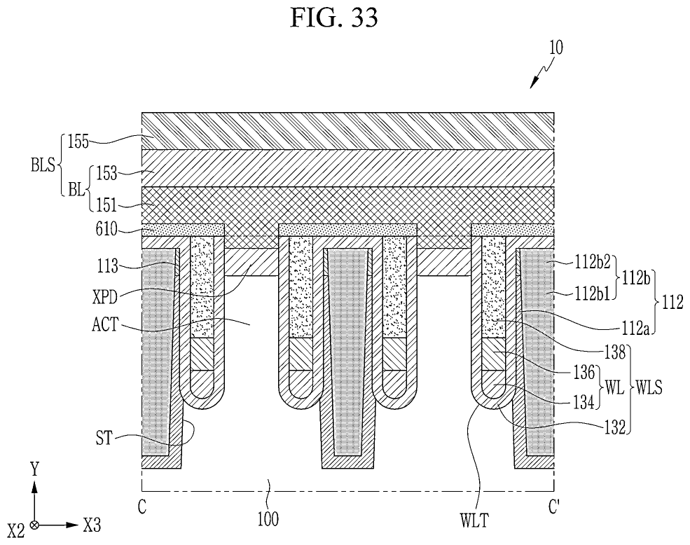

FIG. 31 is a cross-sectional view cut along a line A-A′ of FIG. 30. FIG. 32 is a cross-sectional view cut along a line B-B′ line of FIG. 30. FIG. 33 is a cross-sectional view cut along a line C-C′ of FIG. 30.

Subsequently, referring to FIGS. 30 to 33, the bit line structure BLS may be formed above or on the first insulating pattern 610 and the active region ACT. The bit line structure BLS may extend along the third direction X3, and may cross and overlap the active region ACT and the word line WL. The bit line structure BLS may vertically intersect the word line WL, and the bit line BL may be disposed above the word line WL. One bit line BL may overlap the plurality of active regions ACT adjacent along the third direction X3.

A semiconductor device 10 according to some example embodiments may include a plurality of bit line structures BLS. The plurality of bit line structures BLS may extend in parallel along the third direction X3, and may be spaced apart from each other at regular intervals along the second direction X2.

The bit line structure BLS may be connected to the central portion of the active region ACT through the first pad XPD disposed at the central portion of the active region ACT. However, this is only an example, and a connection form of the bit line structure BLS and the active region ACT may be variously changed.

The bit line structure BLS may be disposed on the first insulating pattern 610 and the first pad XPD. The bit line structure BLS may contact the first pad XPD, and may be electrically connected to the first pad XPD. The bit line structure BLS may be insulated from the second pad XPB by the first insulating pattern 610.

A first bit line pattern 151 and a second bit line pattern 153 may be sequentially formed on the first pad XPD and the first insulating pattern 610. The first bit line pattern 151 may contact the first pad XPD. That is, the first bit line pattern 151 may contact or directly contact the first pad XPD, and the second bit line pattern 153 may contact or directly contact the first bit line pattern 151 and may be connected to the first pad XPD. The first bit line pattern 151 and the second bit line pattern 153 may constitute the bit line BL.

The first bit line pattern 151 may include a metal silicide material. For example, the first bit line pattern 151 may include the metal silicide material such as a cobalt silicide, a nickel silicide, a manganese silicide, a titanium silicide, or the like. The second bit line pattern 153 may include a conductive material. For example, the second bit line pattern 153 may include a polysilicon doped with an impurity or a metal such as W, Mo, Au, Cu, Al, Ni, Co, or the like. In addition, the second bit line pattern 153 may include a metal such as Ti or Ta and/or a metal nitride such as TiN or TaN. In addition, the second bit line pattern 153 may include a metal such as Ti, Ta, or the like and/or a metal nitride such as TIN, TaN, or the like. However, materials included in the first bit line pattern 151 and the second bit line pattern 152 are not limited thereto, and may be variously changed.

Subsequently, the bit line capping layer 155 may be formed on the bit line BL. The bit line BL and the bit line capping layer 155 may form the bit line structure BLS. The bit line capping layer 155 may overlap the bit line BL and the first pad XPD in the fourth direction Y that is a direction perpendicular to the substrate 100.

The bit line capping layer 155 may include a silicon oxide, a silicon nitride, a silicon oxynitride, or a combination thereof. However, a structure and a material of the bit line capping layer 155 are not limited thereto, and may be variously changed.

Subsequently, the bit line spacer 620 may be formed at both sides of the bit line structure BLS. The bit line spacer 620 may cover side surfaces of the bit line capping layer 155 and the bit line BL. The bit line spacer 620 may extend in the fourth direction Y perpendicular to the substrate 100 along the side surface of the bit line structure BLS. The bit line spacer 620 may contact upper surfaces of the first insulating pattern 610 and the first pad XPD.

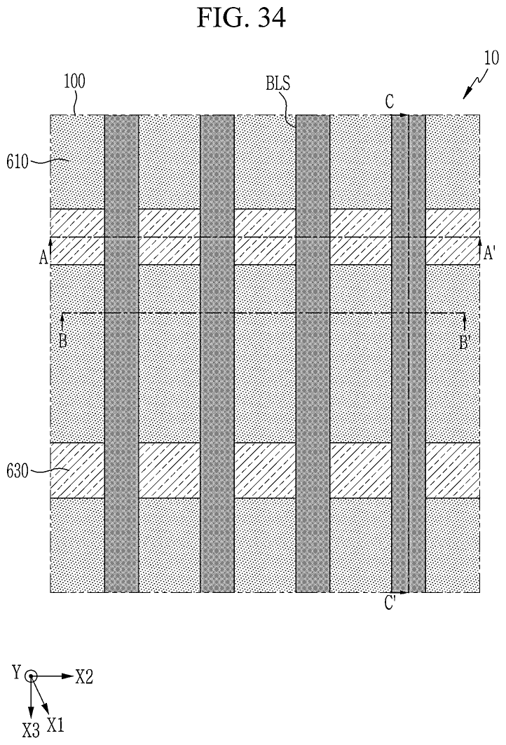

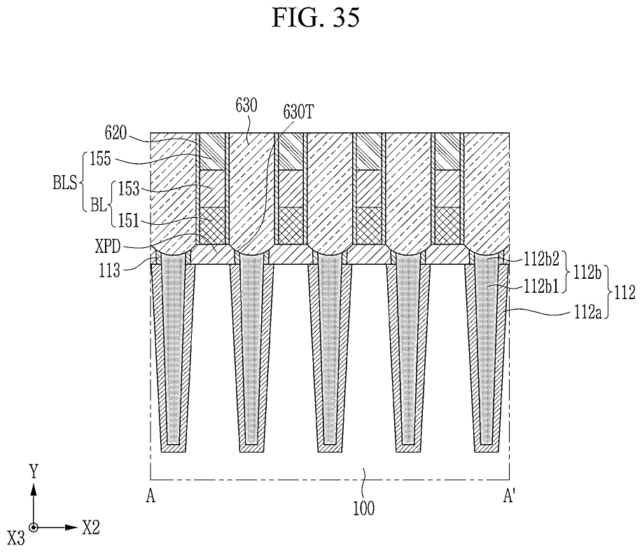

FIG. 35 is a cross-sectional view cut along a line A-A′ of FIG. 34. Since a cross-sectional view cut along a line B-B′ of FIG. 34 and a cross-sectional view cut along a line C-C′ of FIG. 34 are substantially the same as those of FIGS. 32 and 33, the illustration thereof is omitted.

Subsequently, referring to FIGS. 34 and 35, the second insulating pattern 630 may be formed between the bit line structures BLS and between the first insulating patterns 610. On a plane, second insulating patterns 630 may be spaced apart from each other with the bit line structures BLS interposed therebetween in the second direction X2, and may be spaced apart from each other with the first insulating pattern 610 interposed therebetween in the third direction X3.

As shown in FIG. 35, on a cross-section, the second insulating pattern 630 may be disposed between the bit line structures BLS, and may extend in the fourth direction Y perpendicular to the substrate 100. The second insulating pattern 630 may be formed to fill a space between bit line structures BLS. The second insulating pattern 630 may cover the side surface of the bit line spacer 620.

The process step of forming the second insulating pattern 630 may include a process step of forming a second insulating pattern trench 630T by etching portions of the second element isolation layer 112b, the pad spacer 113, and the first pad XPD.

Accordingly, portions of the upper surface of the second element isolation layer 112b, the upper surface of the pad spacer 113, and the upper surface of the first pad XPD contacting the lower surface of the second insulating pattern 630 may include a curved surface, and a bottom surface of the second insulating pattern trench 630T may be defined by the portions of the upper surface of the second element isolation layer 112b, the upper surface of the pad spacer 113, and the upper surface of the first pad XPD. That is, since the portions of the upper surface of the second element isolation layer 112b, the upper surface of the pad spacer 113, and the upper surface of the first pad XPD are etched, the portions of the upper surface of the second element isolation layer 112b, the upper surface of the pad spacer 113, and the upper surface of the first pad XPD may include a shape recessed toward the substrate 100.

The second insulating pattern 630 formed within the second insulating pattern trench 630T may contact the second element isolation layer 112b, the pad spacer 113, and the first pad XPD, and the second insulating pattern 630 may overlap the element isolation layer 112, the pad spacer 113, and the first pad XPD in the fourth direction Y perpendicular to the substrate 100.

In addition, the lower surface of the second insulating pattern 630 formed within the second insulating pattern trench 630T may include a curved surface. That is, the lower surface of the second insulating pattern 630 may protrude toward the element isolation layer 112, and the lower surface of the second insulating pattern 630 may be disposed at a level between the upper surface and the lower surface of the first pad XPD. As described above, since the lower surface of the second insulating pattern 630 includes the curved surface, the second insulating pattern 630 may be disposed to be further extended toward the substrate 100. Accordingly, the second insulating pattern 630 may be relatively stably formed compared with a case where the lower surface of the second insulating pattern 630 does not include the curved surface.

The second insulating pattern 630 may have a single-layer or multi-layer structure including a silicon oxide, a silicon nitride, a silicon oxynitride, or a combination thereof. For example, the second insulating pattern 630 may include a silicon nitride. However, a formation method, a shape, a disposition, and a material of the second insulating pattern 630 are not limited thereto, and may be variously changed.

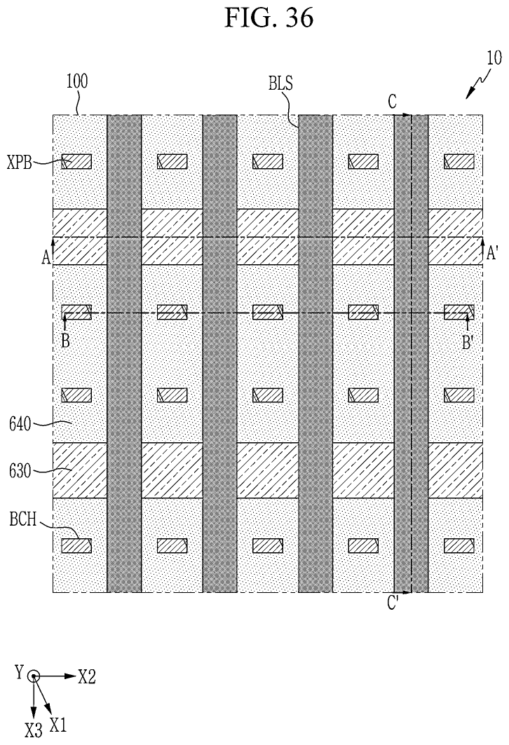

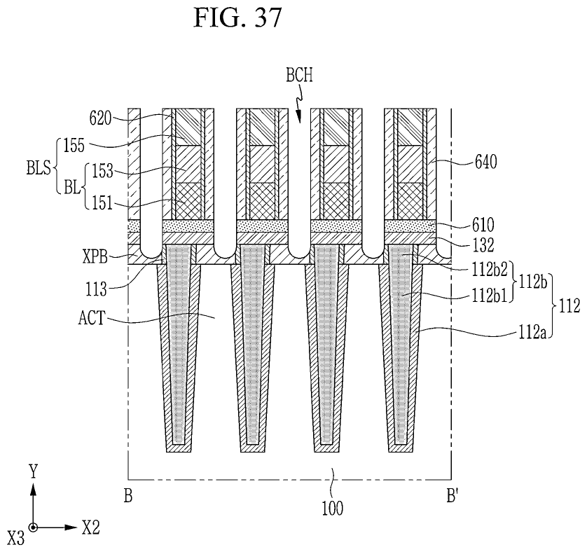

FIG. 37 is a cross-sectional view cut along a line B-B′ of FIG. 36. Since a cross-sectional view cut along a line A-A′ of FIG. 36 and a cross-sectional view cut along a line C-C′ of FIG. 36 are substantially the same as those of FIGS. 35 and 33, the illustration thereof is omitted.

Subsequently, referring to FIGS. 36 and 37, the third insulating pattern 640 disposed between the second insulating patterns 630 and between the bit line structures BLS and exposing the second pad XPB, may be formed.

After the third insulating pattern 640 is formed between the second insulating patterns 630 and between the bit line structures BLS, the third insulating pattern 640 may be patterned to expose the first insulating pattern 610.

Subsequently, the first insulating pattern 610 and the gate insulating layer 132 may be etched using the third insulating pattern 640 as an etching mask to form the buried contact hole BCH exposing the second pads XPB disposed below the gate insulating layer 132.

The third insulating pattern 640 may be disposed between buried contact holes BCH adjacent to the third direction X3 on a plane. However, the present disclosure is not limited thereto, and in some example embodiments, an insulating pattern other than the third insulating pattern 640 may be further formed between the buried contact holes BCH adjacent to the third direction X3 on the plane.

In the process step of forming the buried contact hole BCH, a portion of the pad spacer 113 and a portion of the second pad XPB may be etched together. Accordingly, the upper surface of the pad spacer 113 and the upper surface of the second pad XPB may include a curved surface, and a bottom surface of the buried contact hole BCH may be defined by the portion of the upper surface of the pad spacer 113 and the portion of the upper surface of the second pad XPB. That is, since the portion of the upper surface of the pad spacer 113 and the portion of the upper surface of the second pad XPB are etched, the portion of the upper surface of the pad spacer 113 and the portion of the upper surface of the second pad XPB may include a shape recessed toward the substrate 100.

The third insulating pattern 640 may include a silicon oxide, a silicon nitride, a silicon oxynitride, or a combination thereof. For example, the third insulating pattern 640 may include a silicon oxide.

However, a formation method, a shape, a disposition, and a material of the third insulating pattern 640 are not limited thereto, and may be variously changed.

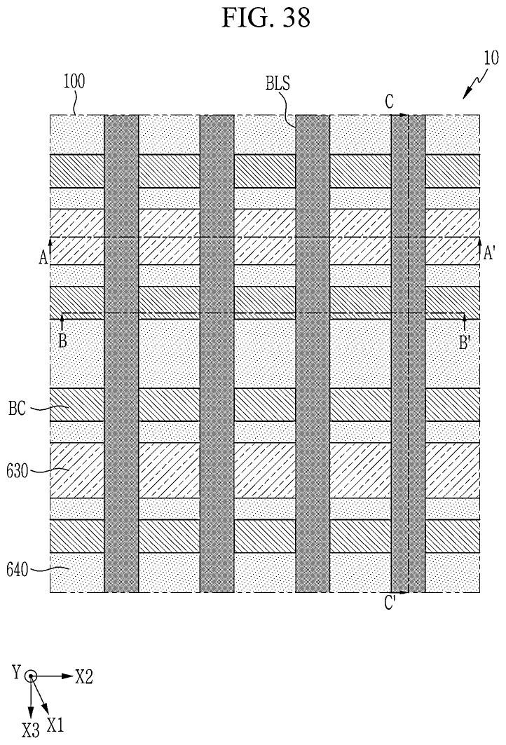

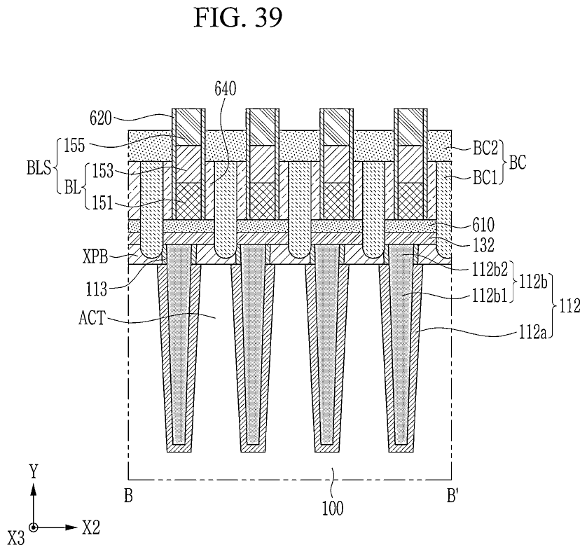

FIG. 39 is a cross-sectional view cut along a line B-B′ of FIG. 38. Since a cross-sectional view cut along a line A-A′ of FIG. 38 and a cross-sectional view cut along a line C-C′ of FIG. 38 are substantially the same as those of FIGS. 35 and 33, the illustration thereof is omitted.

Subsequently, referring to FIGS. 38 and 39, the first buried contact pattern BC1 may be formed within the buried contact hole BCH, and the second buried contact pattern BC2 may be formed on the first buried contact pattern BC1. The first buried contact pattern BC1 and the second buried contact pattern BC2 may form the buried contact BC.

The upper surface of the first buried contact pattern BC1 may be disposed at substantially the same level as the upper surface of the third insulating pattern 640. That is, in the process step of forming the first buried contact pattern BC1 within the buried contact hole BCH, since a portion of the first buried contact pattern BC1 disposed at a level higher than the upper surface of the third insulating pattern 640 is removed by a planarization process such as an etch back process or a chemical mechanical polishing (CMP) process, the upper surface of the first buried contact pattern BC1 may be disposed at substantially the same level as the upper surface of the third insulating pattern 640.

Since the first buried contact pattern BC1 is formed within the buried contact hole BCH, the first buried contact pattern BC1 may contact the second pad XPB and the pad spacer 113. In addition, the lower surface of the first buried contact pattern BC1 may include a curved surface. That is, the lower surface of the first buried contact pattern BC1 may protrude toward the substrate 100.

Subsequently, the second buried contact pattern BC2 may be formed on the first buried contact pattern BC1.

Specifically, a portion of the first buried contact pattern BC1 and a portion of the third insulating pattern 640 are removed to expose a sidewall of the bit line spacer 620. Subsequently, the second buried contact pattern BC2 is formed on the first buried contact pattern BC1.

An upper surface of the second buried contact pattern BC2 may be disposed at a lower level than the upper surface of the bit line spacer 620 and the upper surface of the bit line capping layer 155. Accordingly, an upper side surface of the bit line spacer 620 may be exposed.

The second buried contact pattern BC2 may cover the upper surface of the first buried contact pattern BC1 and the upper surface of the third insulating pattern 640, and may contact the upper side surface of the bit line spacer 620. A width of the second buried contact pattern BC2 may be wider than that of the first buried contact pattern BC1. Accordingly, the buried contact BC including the first buried contact pattern BC1 and the second buried contact pattern BC2 may be formed.

The buried contact BC may include a conductive material. For example, the buried contact BC may include a polysilicon doped with an impurity, a metal silicide, and/or a metal. However, the present disclosure is not limited thereto, and a formation method, a configuration, a shape, a disposition, and a material of the buried contact BC may be variously changed.

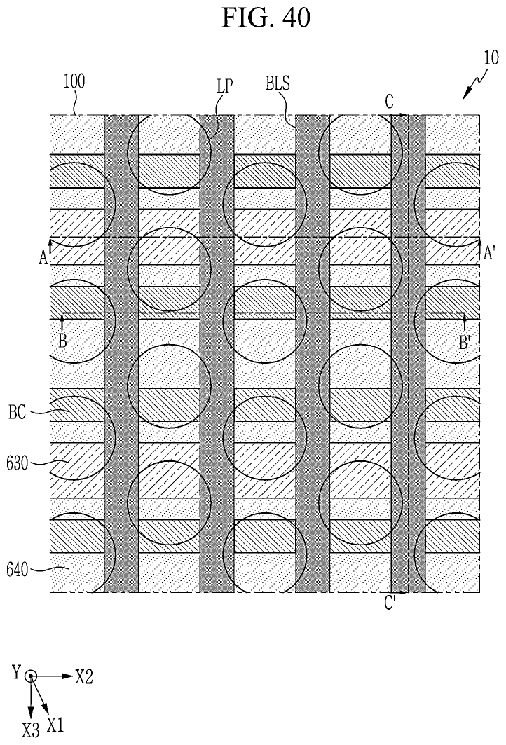

Subsequently, referring to FIG. 40 together with FIGS. 3 to 5, the landing pads LP connected to buried contacts BC may be formed, and the landing pad insulating pattern 660 may be formed between the landing pads LP.

On a plane, the landing pad LP may be formed on the buried contact BC. That is, the landing pads LP may be formed to be spaced apart from each other along the second direction X2 and the third direction X3 by patterning the landing pads LP. That is, the plurality of landing pads LP may be formed in a zigzag form along the second direction X2, and the plurality of landing pads LP may be formed in a row along the third direction X3. For example, the plurality of landing pads LP may be alternately formed in a zigzag form at the left and right sides of the bit line BL.

The landing pad LP may cover an upper surface of the buried contact BC, and may overlap the buried contact BC in the fourth direction Y perpendicular to the buried contact BC. At least a portion of the landing pad LP may overlap the bit line spacer 620 in the fourth direction Y perpendicular to the substrate 100, and may overlap the bit line structure BLS in the fourth direction Y perpendicular to the substrate 100.

The upper surface of the landing pad LP may be disposed at a higher level than the upper surface of the bit line capping layer 155. The bit line spacer 620 may be disposed on both side surfaces of the landing pad LP. In addition, the bit line spacer 620 may be disposed between the landing pad LP and the bit line capping layer 155.

The landing pad LP may contact the buried contact BC. Accordingly, the landing pad LP may be electrically connected to the active region ACT through the buried contact BC. In the process step of forming the landing pad LP, a portion of the bit line capping layer 155 and a portion of the bit line spacer 620 may be etched together.

The landing pad LP a metal, a metal nitride, a polysilicon doped with an impurity, or a combination thereof. For example, the landing pad LP may include tungsten W. In some example embodiments, the landing pad LP may further include a metal silicide layer including a metal silicide material such as a cobalt silicide, a nickel silicide, a manganese silicide, or the like and/or a conductive barrier layer including Ti, TiN, or a combination thereof. However, a formation method, a shape, a disposition, and a material of the landing pad LP are not limited thereto, and may be variously changed.

Subsequently, the landing pad insulating pattern 660 may be formed between the plurality of landing pads LP. The landing pad insulating pattern 660 may be formed to fill a space between the plurality of landing pads LP. The plurality of landing pads LP may be separated from each other by the landing pad insulating pattern 660.

As shown in FIG. 3, the lower surface of the landing pad insulating pattern 660 may be disposed at a level lower than the upper surface of the second insulating pattern 630, and may contact the upper surface of the bit line capping layer 155 and the upper surface of the bit line spacer 620.

In addition, as shown in FIG. 4, the landing pad insulating pattern 660 may contact the upper surface of the bit line capping layer 155 and the upper surface of the bit line spacer 620, and the side surface of the landing pad insulating pattern 660 may be disposed on the upper surface of the bit line capping layer 155. The lower surface of the landing pad insulating pattern 660 may be disposed at a level lower than the upper surface of the bit line capping layer 155, and may contact the second buried contact pattern BC2.

The landing pad insulating pattern 660 may be formed of a single layer or multiple layers. For example, the landing pad insulating pattern 660 may include a first material layer and a second material layer that are stacked.

The first material layer may include a silicon oxide or a low-k material (a low dielectric constant material) having a low dielectric constant such as SiOCH or SiOC, and the second material layer may include a silicon nitride or a silicon oxynitride. However, a formation method, a shape, a material, and the like of the landing pad insulating pattern 660 are not limited thereto, and may be variously changed.

As described above, according to the method for manufacturing the semiconductor device 10 according to some example embodiments, since the first pad XPD and the second pad XPB are formed to be self-aligned between the element isolation layers 112, the photo and etching process step may be omitted. In addition, since the pad pattern XP disposed on the active region ACT is separated into the first pad XPD and the second pad XPB by the word line structure WLS and is self-aligned on the active region ACT, a separate photo and etching process for forming and separating the first pad XPD and the second pad XPB may be omitted.

Accordingly, the pad pattern XP may be prevented or reduced in likelihood from being formed on an undesirable active region ACT due to misalignment in a photo and etching process, and at the same time, the separate photo and etching process may be omitted. Thus, the semiconductor device 10 with improved reliability and productivity may be provided.

While this disclosure has been described in connection with what is presently considered to be example embodiments, it is to be understood that the disclosure is not limited to the disclosed example embodiments, but, on the contrary, is intended to cover various modifications and equivalent arrangements included within the spirit and scope of the appended claims.

What is claimed is:

1. A semiconductor device comprising:
a substrate that includes an active region between element isolation layers;
a word line that overlaps the active region and extends in a first direction;
a bit line that overlaps the active region and extends in a second direction crossing the first direction;
a buried contact connected to the active region;
a first pad between and connecting the active region and the bit line;
a second pad between and connecting the active region and the buried contact; and
a landing pad connected to the buried contact,
wherein each of the element isolation layers includes a first element isolation layer and a second element isolation layer inside the first element isolation layer, and each of the first pad and the second pad are between the element isolation layers.

2. The semiconductor device of claim 1, wherein the second element isolation layer includes a first portion surrounded by the first element isolation layer and a second portion that extends from the first portion and protrudes from an upper surface of the first element isolation layer, and the first pad and the second pad are between second portions of the second element isolation layer.

3. The semiconductor device of claim 2, further comprising:
a pad spacer between the first pad and the second portion of the second element isolation layer and between the second pad and the second portion of the second element isolation layer.

4. The semiconductor device of claim 3, wherein the pad spacer is on the upper surface of the first element isolation layer, and the pad spacer contacts a side surface of the first pad, a side surface of the second pad, and a side surface of the second element isolation layer.

5. The semiconductor device of claim 2, wherein an edge of the first pad and an edge of the second pad are on the first element isolation layer.

6. The semiconductor device of claim 1, wherein the first element isolation layer overlaps the first pad and the second pad in a direction perpendicular to the substrate, and the second element isolation layer does not overlap the first pad and the second pad in the direction perpendicular to the substrate.

7. The semiconductor device of claim 1, wherein the first element isolation layer and the second element isolation layer include different materials.

8. The semiconductor device of claim 1, wherein widths of the first pad and the second pad are greater than a width of an upper surface of the active region.

9. The semiconductor device of claim 1, wherein the element isolation layers have a width decreasing from an upper surface of the element isolation layers to a lower surface of the element isolation layers.

10. The semiconductor device of claim 9, wherein a maximum width of the second element isolation layer is about 3.8 nm or more.

11. The semiconductor device of claim 1, wherein a plurality of active regions extend in a third direction oblique to the first direction and the second direction, the plurality of active regions are spaced apart from each other in parallel along the first direction and the third direction, and both end portions of the active regions adjacent along the first direction are aligned so that the both end portions coincide with each other.

12. The semiconductor device of claim 11, wherein the first pad and the second pad are spaced apart from each other in the third direction.

13. The semiconductor device of claim 1, further comprising a word line capping layer on the word line,
wherein the first pad is between word line capping layers.

14. A semiconductor device comprising:
a substrate including active regions;
an element isolation layer that includes a first element isolation layer and a second element isolation layer on the first element isolation layer and including a protruding portion protruding in a direction perpendicular to an upper surface of the first element isolation layer and is between the active regions;
word lines that overlap the active regions and extend in a first direction;
bit lines that overlap the active regions and extend in a second direction crossing the first direction;
buried contacts connected to the active regions;
first pads connecting between the active regions and the bit lines;
second pads connecting between the active regions and the buried contacts; and
a pad spacer that is between the first pads and the protruding portion of the second element isolation layer and between the second pads and the protruding portion of the second element isolation layer,
wherein the active regions extend in a third direction oblique to the first direction and the second direction, the active regions are spaced apart from each other in parallel along the first direction and the third direction, both end portions of the active regions adjacent along the first direction are aligned so that the both end portions coincide with each other, a lower surface of the pad spacer contacts the first element isolation layer, and a side surface of the pad spacer contacts the second element isolation layer.

15. The semiconductor device of claim 14, wherein central axes of the first pads and central axes of the second pads respectively coincide with central axes of the active regions.

16. The semiconductor device of claim 15, wherein lower surfaces of the first pads and lower surfaces of the second pads respectively contact an upper surface of the first element isolation layer and upper surfaces of the active regions, and side surfaces of the first pads and side surfaces of the second pads respectively contact the pad spacer.

17. A method for manufacturing a semiconductor device, comprising:
forming a first trench defining an active region within a substrate;
forming a first element isolation layer on an upper surface of the active region and within the first trench;
forming a second element isolation layer filling the first trench;
etching the first element isolation layer to form a second trench exposing an upper surface of the active region;
forming a pad pattern on the active region within the second trench;
forming a word line that overlaps the pad pattern and extends in a first direction; and
forming a bit line that overlaps the pad pattern and extends in a second direction crossing the first direction,
wherein the second element isolation layer is at both sides of the second trench, and in the forming of the word line, the pad pattern is separated into a first pad and a second pad by the word line and the first pad is connected to the bit line.

18. The method of claim 17, further comprising forming a pad spacer on the first element isolation layer to cover a side surface of the second element isolation layer after the forming of the second trench.

19. The method of claim 17, wherein in the forming of the pad pattern, a lower surface of the pad pattern is at substantially the same level as an upper surface of the first element isolation layer and an upper surface of the pad pattern is at substantially the same level as an upper surface of the second element isolation layer.

20. The method of claim 17, further comprising:
forming buried contacts connected to the second pad,
wherein the buried contacts are spaced apart from each other along the first direction.
